(19) United States
(12) Patent Application Publication
(10) Pub. No.: US 2026/0050225 A1
(43) Pub. Date: Feb. 19, 2026

(54) PHOTON EFFICIENT FIELD UNIFORMITY ENHANCEMENT FOR INSPECTION TOOLS

(71) Applicant: KLA Corporation, Milpitas, CA (US)

(72) Inventors: Farid Atry, San Jose, CA (US); Alexander Bykanov, Escondido, CA (US); Alon Rosenthal, Weston, CT (US); Rui-Fang Shi, Cupertino, CA (US)

(21) Appl. No.: 19/295,224

(22) Filed: Aug. 8, 2025

Related U.S. Application Data
(60) Provisional application No. 63/682,425, filed on Aug. 13, 2024.

(51) Int. Cl. G03F 7/00

(52) U.S. Cl. CPC G03F 7/706833; G03F 7/706831; G03F 7/706837; G03F 7/706845

(57) ABSTRACT

A swath imaging system may include an illumination source configured to illuminate a sample with an illumination beam, a stage to scan the sample with a scan pattern including swaths extending along a scan direction when implementing the inspection recipe, one or more TDI sensors configured to capture swath images of the sample, and a controller. The plurality of swaths may be distributed along a step direction orthogonal to the scan direction, and at least some of the plurality of swath images overlap along the step direction. The controller may implement the inspection recipe by receiving the plurality of swath images, combining the plurality of swath images into a uniformized image where overlapping portions of the plurality of swath images are combined within the uniformized image, and generating one or more measurements of the sample based on the uniformized image.

### CROSS-REFERENCE TO RELATED APPLICATIONS

The present application claims the benefit under 35 U.S.C. § 119 (e) of U.S. Provisional Application Ser. No. 63/682,425 filed Aug. 13, 2024, entitled PHOTON EFFICIENT FIELD UNIFORMITY ENHANCEMENT FOR INSPECTION TOOLS, naming Farid Atry, Alexander Bykanov, Alon Rosenthal, and Rui-Fang Shi as inventors, which is incorporated herein by reference in the entirety.

### TECHNICAL FIELD

The present disclosure relates to inspection systems for inspection tools for semiconductor manufacturing, and more particularly to photon-efficient field uniformity enhancement techniques for inspection tools using overlapping swath imaging.

### BACKGROUND

Inspection of reticles and/or wafers plays a crucial role in ensuring proper yield in semiconductor manufacturing. As critical dimensions in chip production continue to decrease, inspection tools face increasing demands to improve imaging resolution by reducing effective detector pixel sizes. This trend necessitates higher light intensities at the reticle to compensate for smaller pixels and decreased integration times. However, achieving uniform illumination across the imaging field becomes more challenging, especially for emerging extreme ultraviolet (EUV) inspection tools that operate with low photon counts and high photon shot noise.

Conventional illumination approaches for inspection tools often struggle to balance field uniformity, photon efficiency, and throughput requirements. Critically illuminated systems using plasma sources tend to produce nonuniform illumination spots, while quasi-Kohler illumination configurations can improve uniformity but often at the cost of additional optical components and reduced photon utilization. These limitations can negatively impact inspection sensitivity, reliability, and overall system performance as the industry pushes towards more advanced semiconductor nodes.

### SUMMARY

In some embodiments, a swath imaging system is provided. The swath imaging system may include an illumination source configured to illuminate a sample with an illumination beam when implementing an inspection recipe. The system may include a stage configured to scan the sample with a scan pattern including a plurality of swaths extending along a scan direction when implementing the inspection recipe, and the plurality of swaths may be distributed along a step direction orthogonal to the scan direction. The system may include one or more Time-Delay-Integration (TDI) sensors configured to capture a plurality of swath images of the sample associated with the plurality of swaths when implementing the inspection recipe, and at least some of the plurality of swath images may overlap along the step direction. The system may include a controller including one or more processors configured to execute program instructions causing the one or more processors to implement the inspection recipe by receiving the plurality of swath images, combining the plurality of swath images into a uniformized image such that overlapping portions of the plurality of swath images are combined within the uniformized image, and generating one or more measurements of the sample based on the uniformized image.

In some embodiments, the one or more measurements may include at least one of inspection measurements or metrology measurements.

In some embodiments, combining the plurality of swath images into the uniformized image may compensate for imaging nonuniformities caused by at least one of a beam profile of the illumination beam on the sample, nonuniformities caused by one or more optics imaging the sample onto the one or more TDI sensors, or nonuniformities in light responsivity across the one or more TDI sensors.

In some embodiments, combining the plurality of swath images into the uniformized image may provide that an image nonuniformity metric for the uniformized image is satisfied.

In some embodiments, the image nonuniformity metric may include a measure of variation in at least one of image gray scale intensity, energy per pixel, or photons per pixel across the uniformized image.

In some embodiments, the image nonuniformity metric may be based on a ratio of a difference between maximum and minimum values to a sum of the maximum and minimum values.

In some embodiments, the image nonuniformity metric may have a value of 10% or lower.

In some embodiments, the image nonuniformity metric may have a value of 1% or lower.

In some embodiments, one or more imaging parameters used to generate the plurality of swath images may be selected to achieve the image nonuniformity metric.

In some embodiments, the one or more imaging parameters may include at least one of overlap between the plurality of swath images, a shift between the plurality of swath images along the step direction, a size of at least one of the one or more TDI sensors along the step direction, or a size of the illumination beam on the sample along the step direction.

In some embodiments, the one or more TDI sensors may include two or more TDI sensors, and the one or more imaging parameters may include at least one of overlap between the plurality of swath images, a shift between the plurality of swath images along the step direction, a size of at least one of the one or more TDI sensors along the step direction, or a size of the illumination beam on the sample along the step direction, or a distance between at least some of the two or more TDI sensors along the step direction.

In some embodiments, the one or more imaging parameters used to generate the plurality of swath images may be further selected to achieve a selected inspection time for inspecting a selected portion of the sample.

In some embodiments, the selected inspection time may be equal to or lower than an inspection time achieved with no overlap between the plurality of swath images.

In some embodiments, the one or more imaging parameters used to generate the plurality of swath images may be further selected to achieve a photon utilization of the illumination beam while imaging.

In some embodiments, the photon utilization may be 90% or higher.

In some embodiments, the photon utilization may be 25% or higher.

In some embodiments, combining the plurality of swath images into the uniformized image may include at least one of summing or averaging the overlapping portions of the plurality of swath images.

In some embodiments, a shift between at least some of the plurality of swath images in the step direction may be in a range of 20-50% of a swath width in the step direction.

In some embodiments, a shift between at least some of the plurality of swath images in the step direction may be an integer fraction of the TDI size in that direction.

In some embodiments, a shift between at least some of the plurality of swath images in the step direction may be smaller than an integer fraction of the TDI size in the step direction.

In some embodiments, the one or more TDI sensors may include a single TDI sensor, and at least some adjacent swath images of the plurality of swath images may overlap along the step direction.

In some embodiments, the one or more TDI sensors may include two or more TDI sensors, at least some of the two or more TDI sensors may be separated by a gap along the step direction, and at least some of the plurality of swaths may be separated along the step direction by an integer fraction of the gap.

In some embodiments, the one or more TDI sensors may include two or more TDI sensors, at least some of the two or more TDI sensors may be separated by a gap along the step direction, and at least some of the plurality of swaths may be separated along the step direction by a non-integer fraction of the gap.

In some embodiments, the one or more TDI sensors may include two or more TDI sensors, and at least some of the plurality of swaths may be separated along the step direction by an integer fraction of a size of at least one of the TDI sensors along the step direction.

In some embodiments, the one or more TDI sensors may include two or more TDI sensors, and at least some of the plurality of swaths may be separated along the step direction by a non-integer fraction of a size of at least one of the TDI sensors along the step direction.

In some embodiments, the sample may include at least one of a wafer or a reticle.

In some embodiments, the illumination beam may include wavelengths in an extreme ultraviolet (EUV) spectral region.

In some embodiments, a swath imaging system is provided. The system may include a controller including one or more processors configured to execute program instructions causing the one or more processors to implement an inspection recipe by receiving a plurality of swath images of a sample, such that the plurality of swath images are captured by one or more TDI sensors during implementation of the inspection recipe and at least some of the plurality of swath images overlap along a step direction, combining the plurality of swath images into a uniformized image such that overlapping portions of the plurality of swath images are combined within the uniformized image, and generating measurements of the sample based on the uniformized image.

In some embodiments, the measurements may include at least one of inspection measurements or metrology measurements.

In some embodiments, combining the plurality of swath images into the uniformized image may include at least one of summing or averaging the overlapping portions of the plurality of swath images.

In some embodiments, the plurality of swath images may be captured using an illumination beam having a nonuniform beam profile.

In some embodiments, combining the plurality of swath images into the uniformized image may provide that an image nonuniformity metric for the uniformized image is satisfied.

In some embodiments, one or more imaging parameters used to generate the plurality of swath images may be selected to achieve the image nonuniformity metric.

In some embodiments, the one or more imaging parameters may include at least one of overlap between the plurality of swath images, a width of the one or more TDI sensors, or a width of an illumination beam on the sample along the step direction.

In some embodiments, the one or more imaging parameters used to generate the plurality of swath images may be further selected to achieve a selected inspection time for inspecting a selected portion of the sample.

In some embodiments, the one or more imaging parameters used to generate the plurality of swath images may be further selected to achieve a selected photon utilization of an illumination beam while imaging.

In some embodiments, the one or more TDI sensors may include a single TDI sensor, and at least some adjacent swath images of the plurality of swath images may overlap along the step direction.

In some embodiments, the one or more TDI sensors may include two or more TDI sensors, at least some of the two or more TDI sensors may be separated by a gap along the step direction, and at least some of the plurality of swath images may be separated along the step direction by an integer fraction of the gap.

In some embodiments, a method is provided. The method may include illuminating a sample with an illumination beam having a nonuniform beam profile. The method may include scanning the sample with a scan pattern including a plurality of swaths extending along a scan direction, and the plurality of swaths may be distributed along a step direction orthogonal to the scan direction. The method may include capturing, using one or more TDI sensors, a plurality of swath images of the sample associated with the plurality of swaths, and at least some of the plurality of swath images may overlap along the step direction. The method may include combining the plurality of swath images into a uniformized image such that overlapping portions of the plurality of swath images are combined within the uniformized image. The method may include generating measurements of the sample based on the uniformized image.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of a swath imaging system, according to aspects of the present disclosure.

FIG. 1B illustrates a block diagram of the swath imaging system of FIG. 1A, according to aspects of the present disclosure.

FIG. 2 illustrates a flowchart of a method for enhancing field uniformity in an inspection system, according to aspects of the present disclosure.

FIG. 3 illustrates imaging with different sizes of a TDI sensor relative to a spot size of a Gaussian illumination beam, according to aspects of the present disclosure.

FIG. 4 illustrates two plots illustrating tradeoffs between nonlinearity, TDI sensor size, and photon utilization using the Gaussian illumination beam of FIG. 3, according to aspects of the present disclosure.

FIG. 5 illustrates achieving illumination uniformity by combining overlapping swath images into a uniformized image using the Gaussian illumination beam of FIG. 3, according to aspects of the present disclosure.

FIG. 6 illustrates a graph plot showing nonuniformity versus TDI size for different swath overlap percentages using the Gaussian illumination beam of FIG. 3, according to aspects of the present disclosure.

FIG. 7 illustrates inspection time as a function of TDI size for different overlap percentages and the Gaussian illumination beam of FIG. 3, according to aspects of the present disclosure.

FIG. 8 illustrates inspection time as a function of TDI size for different overlap percentages and the Gaussian illumination beam of FIG. 3, according to aspects of the present disclosure.

FIG. 9 illustrates illumination nonuniformity as a function of inspection time for a Gaussian light source with fixed source size for different overlap percentages and different retrace times, according to aspects of the present disclosure.

FIG. 10 illustrates illumination nonuniformity as a function of inspection time for fixed TDI sensor size and a Gaussian light source with different overlap percentages and different retrace times, according to aspects of the present disclosure.

FIG. 11 illustrates illumination nonuniformity and photon utilization as a function of TDI sensor size for a Lorentzian illumination beam and a nonoverlapping configuration, according to aspects of the present disclosure.

FIG. 12 illustrates inspection time as a function of TDI size for different overlap percentages and the Lorentzian illumination beam of FIG. 11, according to aspects of the present disclosure.

FIG. 13 illustrates inspection time as a function of TDI size for different overlap percentages and the Lorentzian illumination beam of FIG. 11, according to aspects of the present disclosure.

FIG. 14 illustrates illumination nonuniformity as a function of inspection time for the Lorentzian light source of FIG. 11 with TDI sensor size for different overlap percentages and different retrace times, according to aspects of the present disclosure.

FIG. 15A depicts three plots showing illumination nonuniformity using the Gaussian illumination beam of FIG. 3 and a multi-TDI sensor configuration, according to aspects of the present disclosure.

FIG. 15B illustrates achieving illumination uniformity by combining overlapping swath images from the three TDI sensors distributed along a step direction across the Gaussian illumination beam of FIG. 3, according to aspects of the present disclosure.

FIG. 15C illustrates the formation of a uniformized image using the multi-TDI sensor configuration of FIGS. 15A and 15B, according to aspects of the present disclosure.

FIG. 16 illustrates two swathing methods for an inspection system with multiple TDI sensors in a 2×2 grid pattern, according to aspects of the present disclosure.

FIG. 17 illustrates illumination nonuniformity and photon utilization as a function of TDI sensor size for the Gaussian illumination beam of FIG. 3 for different overlap percentages when using a 3×3 grid of TDI sensors separated by gaps the same size as the TDI sensors, according to aspects of the present disclosure.

FIG. 18 illustrates illumination nonuniformity and photon utilization as a function of TDI sensor size for the Gaussian illumination beam of FIG. 3 for different overlap percentages when using a 3×3 grid of TDI sensors separated by gaps half the size as the TDI sensors, according to aspects of the present disclosure.

FIG. 19 illustrates illumination nonuniformity and photon utilization as a function of TDI sensor size for the Gaussian illumination beam of FIG. 3 for different overlap percentages when using a 2×2 grid of TDI sensors separated by gaps the same size as the TDI sensors, according to aspects of the present disclosure.

FIG. 20 illustrates illumination nonuniformity and photon utilization as a function of TDI sensor size for the Gaussian illumination beam of FIG. 3 for different overlap percentages when using a 2×2 grid of TDI sensors separated by gaps the same size as the TDI sensors, according to aspects of the present disclosure.

FIG. 21 illustrates illumination nonuniformity and photon utilization as a function of TDI sensor size for the Lorentzian illumination beam of FIG. 11 for different overlap percentages when using a 3×3 grid of TDI sensors separated by gaps the same size as the TDI sensors, according to aspects of the present disclosure.

FIG. 22 illustrates illumination nonuniformity and photon utilization as a function of TDI sensor size for the Lorentzian illumination beam of FIG. 11 for different overlap percentages when using a 2×2 grid of TDI sensors separated by gaps the same size as the TDI sensors, according to aspects of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to swathing imaging systems and methods for providing uniform imaging in the presence of nonuniformities across the swaths. In embodiments, swath images are generated that at least partially overlap and the swath images are combined to create a uniformized image with high image uniformity.

The systems and methods disclosed herein may generate highly uniform images in the presence of various types of imaging nonuniformities including, but not limted to, illumination nonuniformities arising from the beam profile of the illumination source, optical nonuniformities caused by illumination or imaging optics, or detector nonuniformities resulting from variations in pixel responsivity across the sensor array. For example, many illumination beams have a nonuniform beam profile (e.g., a Gaussian, Lorentzian, or other beam profile). As another example, optical nonuniformities may arise from coating variations or alignment imperfections in lenses, mirrors, or other optical components. As another example, detector nonuniformities may result from manufacturing variations in applied coatings, pixel sensitivity, or aging effects across different regions.

Overlapping swath imaging as disclosed herein may compensate for these various sources of nonuniformity by ensuring that each location on the sample is imaged in multiple swaths, allowing the combination of overlapping swath images to average out or otherwise mitigate the effects of these nonuniformities in the final uniformized image. This approach offers significant advantages over conventional methods that require precise tuning of illumination optics, detector calibration, and system alignment to achieve uniformity within individual swaths. By leveraging image processing to combine overlapping swaths rather than attempting to perfect each individual swath, the disclosed techniques may reduce system complexity, lower manufacturing tolerances, and provide more robust performance across varying operating conditions. Additionally, this method may allow for more cost-effective system designs since it does not require expensive optical components or complex calibration procedures to achieve the desired uniformity levels. Further, in many applications, overlapping swath imaging may achieve equivalent or even better throughput than traditional non-overlapping swath imaging approaches. For example, higher throughput may be achieved in some cases using faster scanning speeds while maintaining a required photon count per pixel in a uniformized image, which can compensate for any increased number of swaths and associated overhead time.

The systems and methods disclosed herein may be suitable for any type of swath imaging tool using any type of illumination source providing light in any spectral range, but may be particularly beneficial for an inspection and/or metrology tool using an illumination source that has a nonuniform beam profile and for which efficient photon utilization is desired (e.g., photon-limited or photon-starved conditions). As an illustration, emerging extreme ultraviolet (EUV) inspection tools often have highly nonuniform illumination profiles at a mask plane, relatively low photon count (e.g., compared to sources in other spectral ranges), and/or high photon shot noise. Most conventional extreme ultraviolet (EUV) light sources create a plasma to generate EUV photons. A plasma source is relatively nonuniform by nature and can be approximated by a 2-dimensional Gaussian or Lorentzian function. As a result, a critical illumination condition also produces a highly nonuniform illumination profile. Techniques to improve uniformity of the illumination beam profile directly through either Kohler (or quasi-Kohler) illumination configurations or high magnification configurations require expensive optical elements or have low photon efficiency.

Some embodiments of the present disclosure are directed to optimizing various parameters such as swath overlap percentage, sensor dimensions, and illumination beam characteristics to achieve desired performance targets. These parameters may be tuned to balance tradeoffs between uniformity, photon efficiency, and inspection speed for different sample types and inspection recipes.

The techniques disclosed herein may be applicable to both single TDI sensor (time-delay-integration) configurations and multi-TDI sensor arrangements. In multi-TDI configurations, the spacing and arrangement of TDI sensors may be optimized in conjunction with the swath overlap to further enhance uniformity and efficiency.

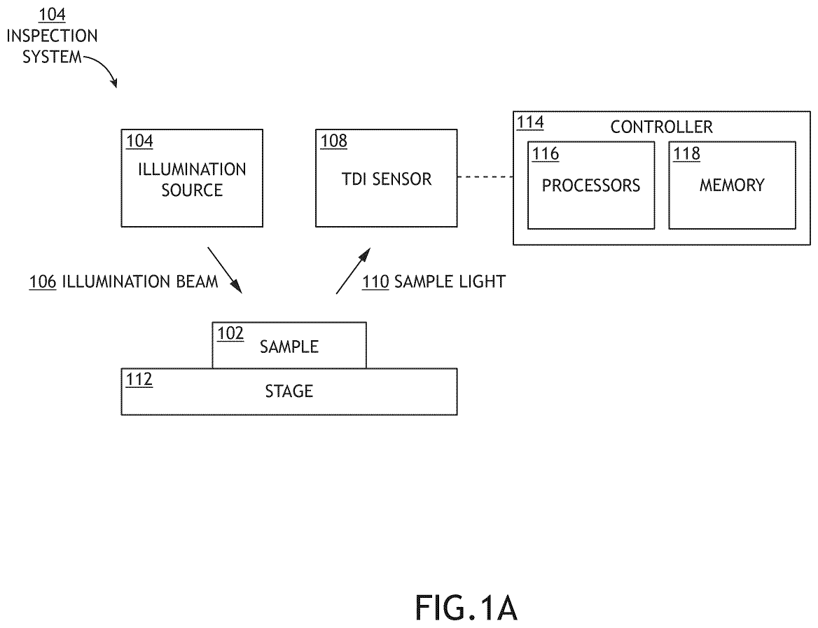

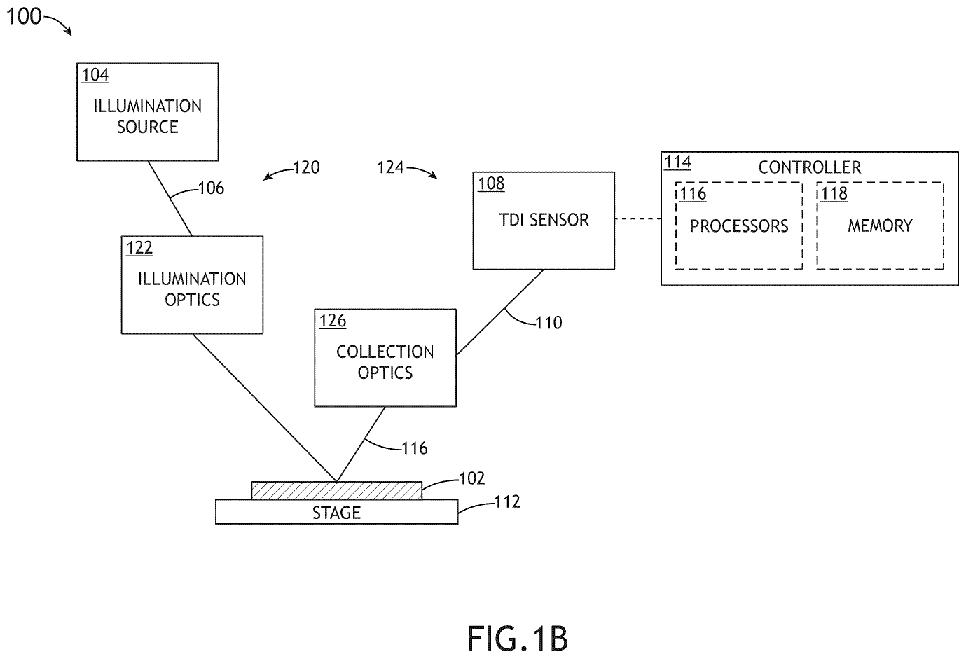

Referring now to FIGS. 1A-22, systems and methods for inspection metrology using overlapping swath imaging is described in greater detail, in accordance with one or more embodiments of the present disclosure.

FIG. 1A illustrates a block diagram of a swath imaging system 100, in accordance with one or more embodiments of the present disclosure.

The swath imaging system 100 may be implemented as any type of imaging tool in which swath images of a sample 102 are generated including, but not limited to, an inspection tool or a metrology tool such as those used in semiconductor manufacturing or other precision manufacturing processes. In some embodiments, the swath imaging system 100 may be configured as a wafer inspection tool for detecting defects, particles, or other anomalies on semiconductor wafers during various stages of the manufacturing process. In some cases, the system may be implemented as a reticle or photomask inspection tool for identifying defects or pattern variations in lithographic masks used in semiconductor fabrication. The swath imaging system 100 may also be configured as a metrology tool for measuring critical dimensions, overlay accuracy, or other dimensional parameters of features on semiconductor devices. In some applications, the system may be adapted for surface inspection of other types of manufactured components such as flat panel displays, printed circuit boards, or optical components. The swath imaging system 100 may further be implemented in research and development environments for characterizing new materials, processes, or device structures, where high-resolution imaging with uniform illumination across large areas is beneficial for accurate analysis and measurement.

The swath imaging system 100 may include an illumination source 104 configured to direct an illumination beam 106 onto a sample 102 positioned on a stage 112. One or more TDI sensors 108 may be positioned to receive sample light 110 from the sample 102 and generate swath images of the sample 102 as the sample is translated along a scan direction by the stage 112. The swath imaging system 100 may also include a controller 114 including processors 116 and memory 118.

The illumination source 104 may generate the illumination beam 106 which illuminates the sample 102. In some cases, the illumination beam 106 may have a nonuniform beam profile. For example, the illumination beam 106 may have a Gaussian or Lorentzian intensity distribution. The illumination source 104 may include any suitable light source for sample inspection such as, but not limited to, a laser, LED, lamp, or plasma source. In some embodiments, the illumination source 104 may provide light in the extreme ultraviolet (EUV) spectral region.

The sample 102 may be any object suitable for inspection, such as a semiconductor wafer, a photomask, a reticle, or other manufactured component. The sample 102 may be supported by the stage 112, which may move the sample 102 relative to the illumination beam 106 and TDI sensor 108. In some cases, the stage 112 may scan the sample 102 with a scan pattern including multiple swaths extending along a scan direction. The swaths may be distributed along a step direction orthogonal to the scan direction. The stage 112 may include linear motors, air bearings, or any other other positioning mechanisms.

The one or more TDI sensors 108 may be configured to capture a plurality of swath images of the sample 102 as the sample 102 is scanned along a scan direction. In some embodiments, at least some of the plurality of swath images may overlap along the step direction. The TDI sensors 108 may be charge-coupled devices (CCDs) or complementary metal-oxide-semiconductor (CMOS) image sensors operating in a time-delay integration mode. A TDI sensor 108 may have any size, shape or number of pixels. For example, a TDI sensor 108 may have multiple pixels arranged in a one-dimensional (1D) array or a two-dimensional (2D) array, where at least some of the pixels are distributed along a step direction orthogonal to the scan direction. A TDI sensor 108 may further be suitable for scanning in a single direction or multiple directions.

In some embodiments, the swath imaging system 100 may utilize a single TDI sensor 108, where the single TDI sensor 108 captures overlapping swath images as the sample 102 is scanned along a scan direction with step sizes along a step direction that are smaller than a width of the TDI sensor 108, resulting in overlap between adjacent swaths. In some embodiments, the system may employ a multi-TDI sensor configuration, where multiple TDI sensors 108 are arranged in a grid pattern (e.g., a 2×2 grid, a 3×3 grid, or the like) to capture multiple swath images simultaneously across different portions of the illumination field. In the multi-TDI configuration, the sample 102 may be scanned with step sizes equal to or smaller than the width of each TDI sensor 108, depending on the desired overlap between swaths.

The controller 114 may coordinate the operation of the various components of the swath imaging system 100. The processors 116 may execute instructions stored in memory 118 to perform any of the described herein either directly or indirectly by generating control signals to direct other components internal or external to the swath imaging system 100. For example, the controller 114 may be configured to, but is not limited to, receive the plurality of swath images captured by the TDI sensors 108, combine the swath images into a uniformized image, and generate inspection measurements of the sample 102 based on the uniformized image.

The one or more processors 116 of the controller 114 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 116 may include any device configured to execute algorithms and/or instructions (e.g., program instructions stored in memory). In some embodiments, the one or more processors 116 may be embodied as a desktop computer, mainframe computer system, workstation, image computer, parallel processor, networked computer, or any other computer system configured to execute a program configured to operate or operate in conjunction with the system, as described throughout the present disclosure.

The memory 118 may include any storage medium known in the art suitable for storing program instructions executable by the associated one or more processors 116. For example, the memory 118 may include a non-transitory memory medium. By way of another example, the memory 118 may include, but is not limited to, a read-only memory (ROM), a random-access memory (RAM), a magnetic or optical memory device (e.g., disk), a magnetic tape, a solid-state drive and the like. It is further noted that memory 118 may be housed in a common controller housing with the one or more processors 116. In some embodiments, the memory 118 may be located remotely with respect to the physical location of the one or more processors 116 and controller 114. For instance, the one or more processors 116 of the controller 114 may access a remote memory (e.g., server), accessible through a network (e.g., internet, intranet and the like).

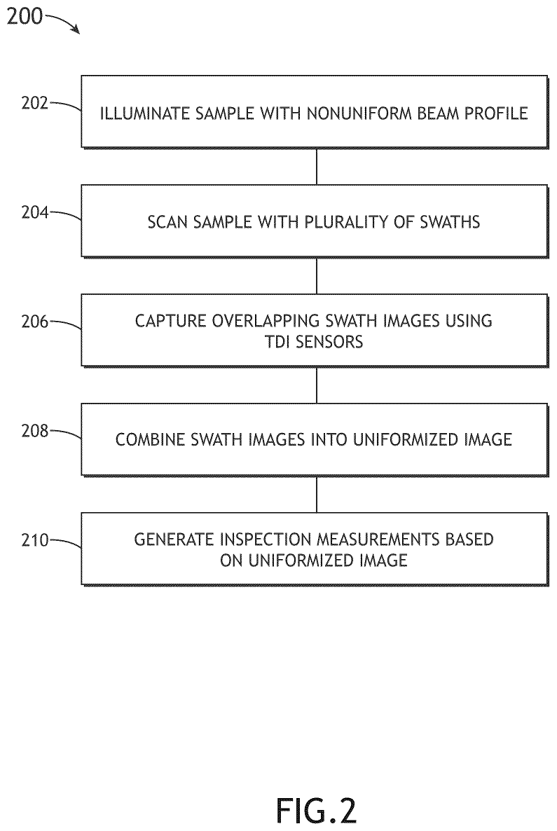

FIG. 2 illustrates a flowchart of a method 200 for enhancing image uniformity in an inspection system, in accordance with one or more embodiments of the present disclosure. The embodiments and enabling technologies described previously herein in the context of the swath imaging system 100 should be interpreted to extend to the method 200. For example, the processors 116 of the controller 114 may be configured to execute program instructions stored on the memory 118, where the program instructions cause the processors 116 to perform any of the steps of the method 200 either directly or indirectly (e.g., by generating control signals to direct another component to perform an action). However, the method 200 is not limited to the architecture of the swath imaging system 100.

In some embodiments, the method 200 includes a step 202 of illuminating a sample with a nonuniform beam profile. The illumination beam 106 may have a nonuniform intensity distribution on the sample 102 such as, but not limited to, a Gaussian or Lorentzian profile. For example, the illumination source 104 of the swath imaging system 100 may generate the illumination beam 106 with a nonuniform intensity distribution such as, but not limited to, a Gaussian or Lorentzian profile. In some cases, the illumination source 104 may include any suitable light source for sample inspection such as, but not limited to, a laser, LED, lamp, or plasma source. In some embodiments, the illumination source 104 may provide light in the extreme ultraviolet (EUV) spectral region.

In some embodiments, the method 200 includes a step 204 of scanning the sample with a plurality of swaths. This scanning step involves moving the sample relative to the illumination beam in a systematic pattern to capture multiple overlapping images, referred to herein as swath images. In some embodiments, the method 200 includes a step 206 of capturing overlapping swath images using one or more TDI sensors.

The plurality of swaths typically extend along a scan direction and are distributed along a step direction that is orthogonal to the scan direction. Various scan patterns may be employed to achieve the desired overlap between swaths and associated swath images. For example, a unidirectional scan pattern may be implemented in which all swaths are scanned in the same direction (e.g., left-to-right), with the sample returning to a starting position after each swath and stepping in the orthogonal direction before beginning the next swath. This approach may be beneficial for samples that are sensitive to directional illumination effects. As another example, a bidirectional scan pattern may be implemented in which alternating swaths are scanned in opposite directions (e.g., left-to-right followed by right-to-left), which can reduce overall inspection time by eliminating return movements. Serpentine patterns, where the scan direction alternates while maintaining continuous motion in the step direction, may also be employed to minimize acceleration and deceleration events.

Overlapping swaths can be achieved through various approaches. In some embodiments, step sizes along the step direction are smaller than a width of the imaging field of view of a TDI sensor (e.g., a projection of the TDI sensor onto the sample), creating regions where adjacent swaths capture the same portion of the sample. For example, a 50% overlap may be achieved when the step size is half the width of the imaging field of view, while a 75% overlap corresponds to a step size that is one-quarter of the imaging field of view. In some embodiments, the shift between at least some of the plurality of swath images along the step direction may be in a range of 20-50% of a swath width in that direction. In some embodiments using multiple TDI sensors arranged in an array configuration, the step size may either be selected to be smaller than a width of any of the TDI sensors such that adjacent swaths capture the same portion of the sample or the step size may be selected to be equal to or greater than a width of any of the TDI sensors such that locations on the sample are imaged with different TDI sensors in different swaths.

The degree of overlap can be precisely controlled by adjusting the step size along the step direction (e.g., shift), with higher overlap percentages generally providing better uniformity enhancement at the cost of increased inspection time. The overlap percentage may be selected based on the specific illumination profile characteristics, desired uniformity targets, and throughput requirements for a particular inspection application. In many practical implementations, shifts between adjacent swath images in the range of 20-50% of the swath width may provide optimal performance characteristics. A 20% shift (corresponding to 80% overlap) may maximize uniformity enhancement but may require longer inspection times due to the high degree of overlap, while a 50% shift (corresponding to 50% overlap) may provide a more balanced approach that achieves substantial uniformity improvement with more moderate impact on inspection time. Shifts in the 30-40% range may offer intermediate performance, allowing for fine-tuning of the uniformity-throughput tradeoff based on specific application requirements.

As an illustration using the swath imaging system 100, the stage 112 may translate the sample 102 relative to the illumination beam 106 along a scan direction. The plurality of swaths may extend along the scan direction and be distributed along a step direction orthogonal to the scan direction. In some cases, the stage 112 may move the sample 102 with step sizes smaller than a width of the TDI sensor 108 along the step direction, resulting in overlap between adjacent swaths. For example, if the TDI sensor 108 has an imaged field of view width of 100 microns on the sample 102, the stage 112 might move the sample 102 by step sizes of 50 microns between adjacent swaths to achieve a 50% overlap (corresponding to a 50% shift), or by 25 microns to achieve a 75% overlap (corresponding to a 25% shift). In implementations where shifts are maintained in the 20-50% range, step sizes might range from 50 microns (50% shift) to 80 microns (20% shift), providing various degrees of overlap that balance uniformity enhancement with inspection efficiency. The stage 112 may implement either unidirectional or bidirectional scanning based on the specific inspection recipe requirements, with the controller 114 coordinating the precise timing of stage movements with the image acquisition by the TDI sensor 108 to ensure proper registration of the overlapping swath images for subsequent combination and analysis.

In some embodiments utilizing a multi-TDI sensor configuration, the stage 112 may move the sample 102 with step sizes equal to the width of each TDI sensor 108 along the step direction. This scan profile may result in swath images from a given TDI sensor 108 not overlapping with each other, while swath images from different TDI sensors 108 in the array may overlap. Such a configuration may allow for efficient coverage of the sample 102 while still providing overlapping data between adjacent TDI sensors 108 for uniformity enhancement.

In some embodiments, the method 200 includes a step 208 of combining the swath images into a uniformized image.

Any method of combining overlapping swath images to achieve enhanced uniformity is contemplated within the spirit and scope of the present disclosure. For example, combining the plurality of swath images into a uniformized image may comprise at least one of summing or averaging the overlapping portions of the plurality of swath images. It is contemplated herein that combining swath images into a new image (e.g., the uniformized image) may create an effective uniform illumination distribution across the uniformized image, despite the nonuniform beam profile of the illumination beam 106 used to generate any particular swath image. The specific combination method may be selected based on the inspection application, sample characteristics, illumination profile, and desired uniformity targets.

In some embodiments, pixel-by-pixel summing of overlapping regions may be implemented by adding intensity values at corresponding pixel locations from multiple swath images to create a combined image with enhanced signal-to-noise ratio and improved uniformity. In some embodiments, pixel-by-pixel averaging of overlapping regions may be implemented by summing intensity values at corresponding pixel locations from multiple swath images and dividing by the number of overlapping swaths. In some embodiments, weighted averaging may be implemented where pixels from different swaths are assigned weights based on their position relative to the center of each swath's illumination profile, with higher weights assigned to pixels closer to the center of a swath where signal-to-noise ratio may be higher. In some embodiments, adaptive combining algorithms may be implemented that analyze local image characteristics to determine optimal combination methods for different regions of the image.

Any type of registration technique for aligning overlapping swath images prior to their combination into the uniformized image may be within the spirit and scope of the present disclosure. In some embodiments, registration may be based on stage position data, where the known positions of the stage 112 during image acquisition are used to align the swath images. In some cases, image-based registration techniques may be employed, such as feature matching algorithms that identify and align common features or patterns across overlapping regions of adjacent swath images. In some embodiments, fiducial markers or reference structures on the sample 102 may be used as registration points. The swath imaging system 100 may also utilize a combination of multiple registration techniques to achieve precise alignment. For multi-TDI sensor configurations, registration may involve aligning swath images from different TDI sensors 108 as well as overlapping swaths from individual sensors. In some cases, the registration process may be performed in real-time as images are acquired, while in other implementations, registration may be carried out as a post-processing step after all swath images have been captured.

As an illustration using the swath imaging system 100, the controller 114 may receive the plurality of swath images from the TDI sensors 108 and store them in memory 118. The processors 116 may execute instructions stored in the memory 118 to implement various image combination algorithms such as, but not limited to, registration, summing, averaging, weighted averaging, or the like. For multi-TDI sensor 108 configurations, the controller 114 may process swath images from different TDI sensors 108 separately before combining them into the final uniformized image. The uniformized image may then be stored in memory 118 for subsequent inspection analysis.

The uniformized image may be provided in various formats to accommodate different processing requirements and system architectures. In some implementations, the uniformized image may be stored as a single, comprehensive image file encompassing the entire inspected area of the sample. Alternatively, the uniformized image may be segmented into multiple smaller image sections or tiles, which can be stored and processed independently. This segmented approach may allow for parallel processing of different image regions, potentially improving computational efficiency and reducing memory requirements. In some cases, the uniformized image data may be maintained in a distributed format, with different portions stored across multiple storage devices or nodes in a networked system. The specific storage and organization method for the uniformized image may be selected based on factors such as the size of the inspected area, available computational resources, and the particular requirements of downstream analysis algorithms.

In some embodiments, the method 200 includes a step 210 of generating inspection measurements based on the uniformized image. The processors 116 may analyze the uniformized image to detect defects, measure critical dimensions, or perform other inspection tasks on the sample 102. The uniformized image may provide consistent detection sensitivity across the field of view due to the enhanced illumination uniformity achieved through the overlapping swath technique.

Referring generally to the method 200, any of the processing steps of the method 200 may be performed in real-time as the swath images are captured or as a post-processing step after all swath images have been acquired, depending on the specific inspection recipe requirements.

Additionally, the method 200 may include a step of selecting imaging conditions to provide a desired performance using any suitable performance metric. These imaging conditions may include, but are not limited to, TDI sensor size, imaging field of view of the TDI sensor (projection of the TDI sensor onto the sample), number or distribution of TDI sensors, spot size of the illumination beam relative to the imaging field of view, overlap between swath images, and scan speed. The selection of these imaging conditions may be based on various performance metrics such as illumination uniformity in a uniformized image and photon efficiency. In some cases, the imaging conditions may be optimized to balance multiple performance metrics, as different applications may prioritize certain metrics over others.

In some embodiments, combining the plurality of swath images into the uniformized image may provide that an image nonuniformity metric for the uniformized image is satisfied. Any image nonuniformity metric may be utilized such as, but not limited to, a measure of variation in at least one of image gray scale intensity, energy per pixel, or photons per pixel across the uniformized image. In some embodiments, the image nonuniformity metric may be based on a ratio of a difference between maximum and minimum values to a sum of the maximum and minimum values. In some embodiments, the image nonuniformity metric may have a value of 10% or lower. In some embodiments, the image nonuniformity metric may have a value of 1% or lower. However, these are merely illustrations and should not be interpreted as limiting the scope of the present disclosure.

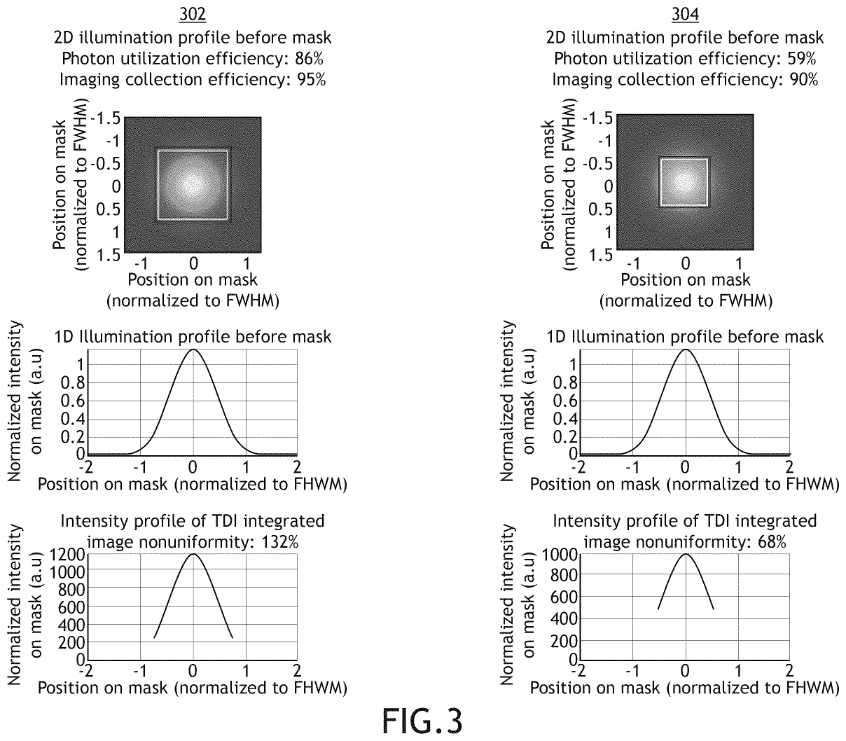

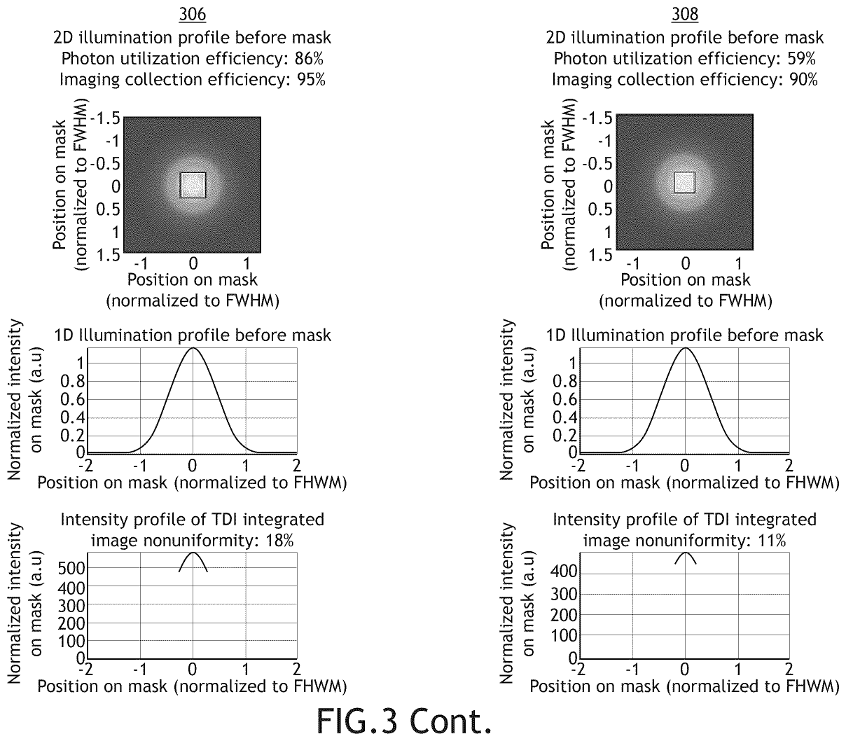

FIGS. 3-22 illustrate various aspects of traditional non-overlapping imaging and the generation of uniformized images by combining overlapping swath images. These figures provide detailed analyses and comparisons of different imaging configurations, illumination profiles, and performance metrics relevant to the disclosed inspection techniques.

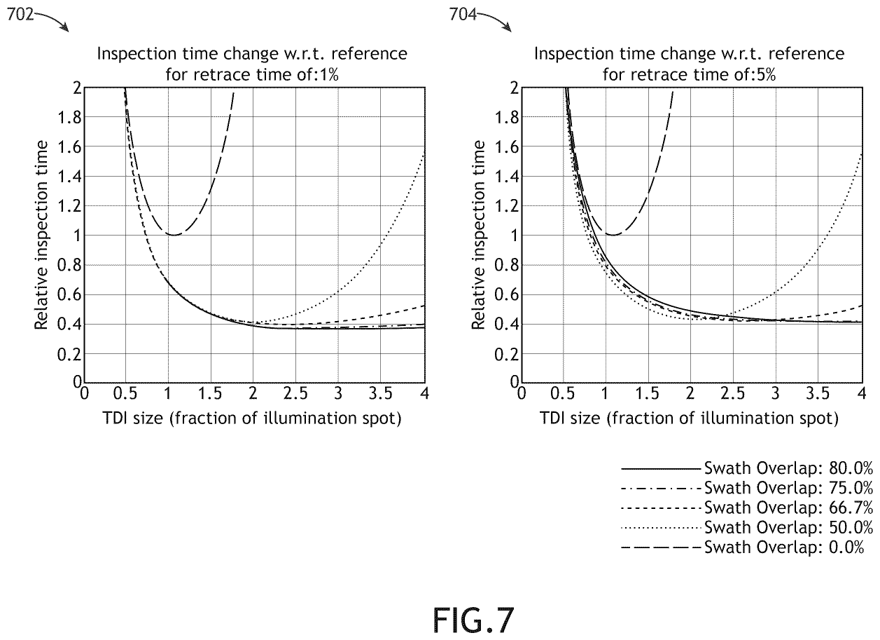

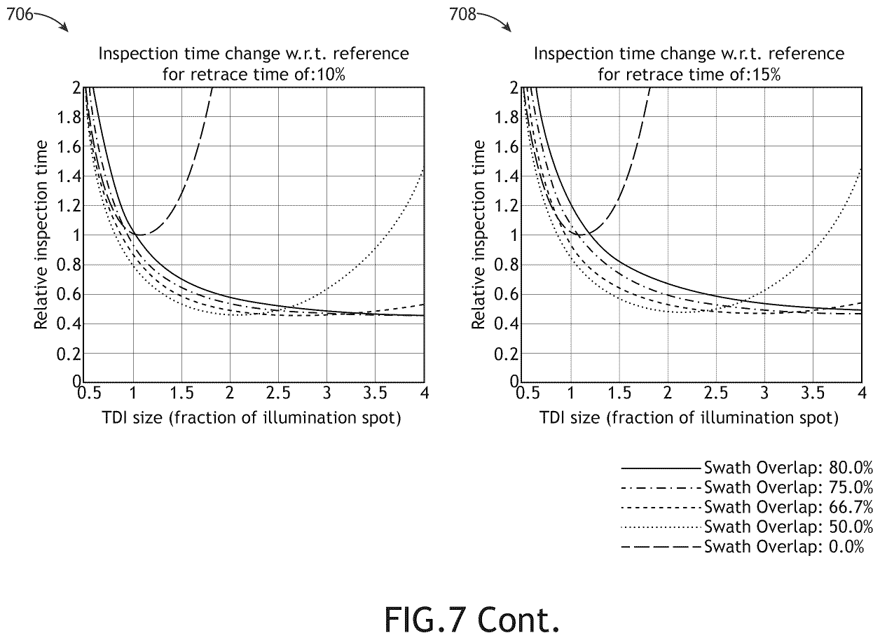

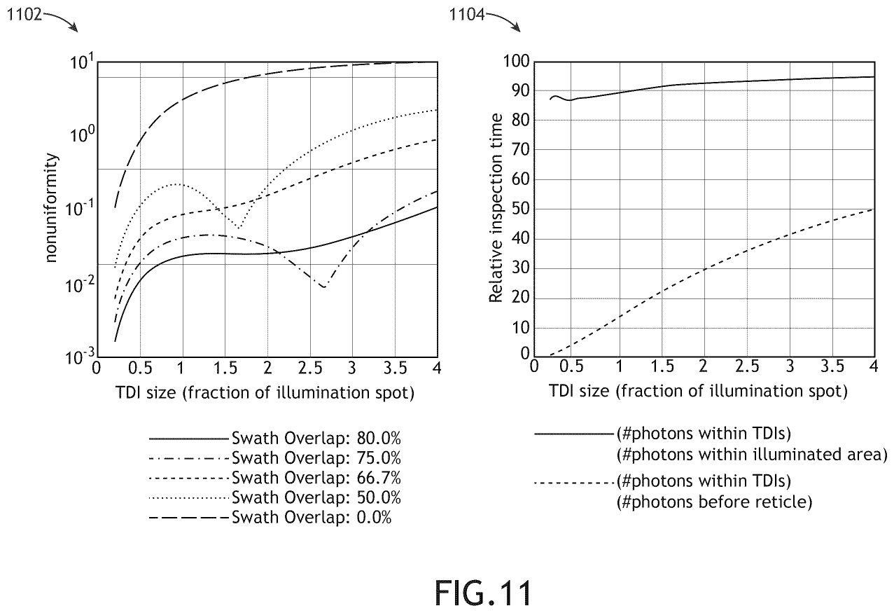

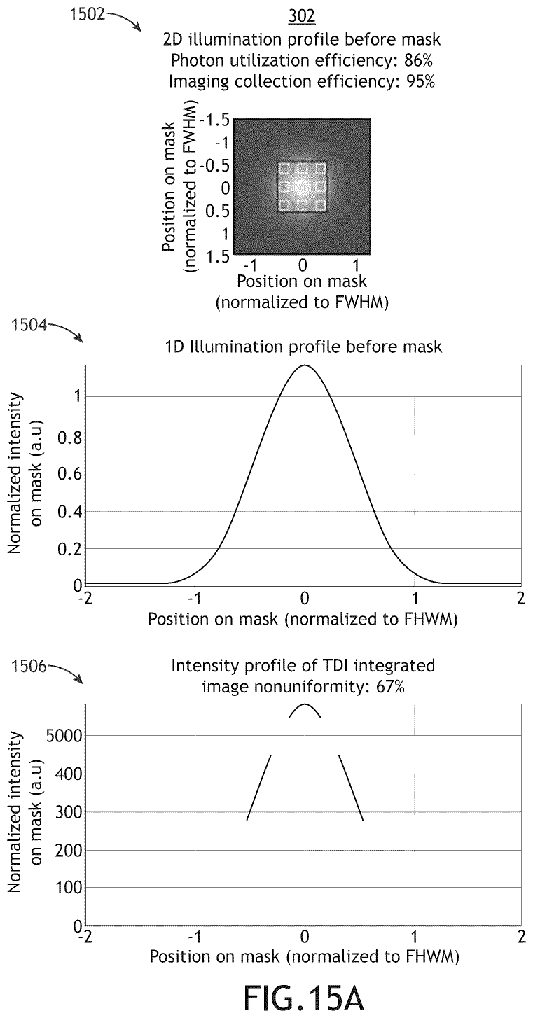

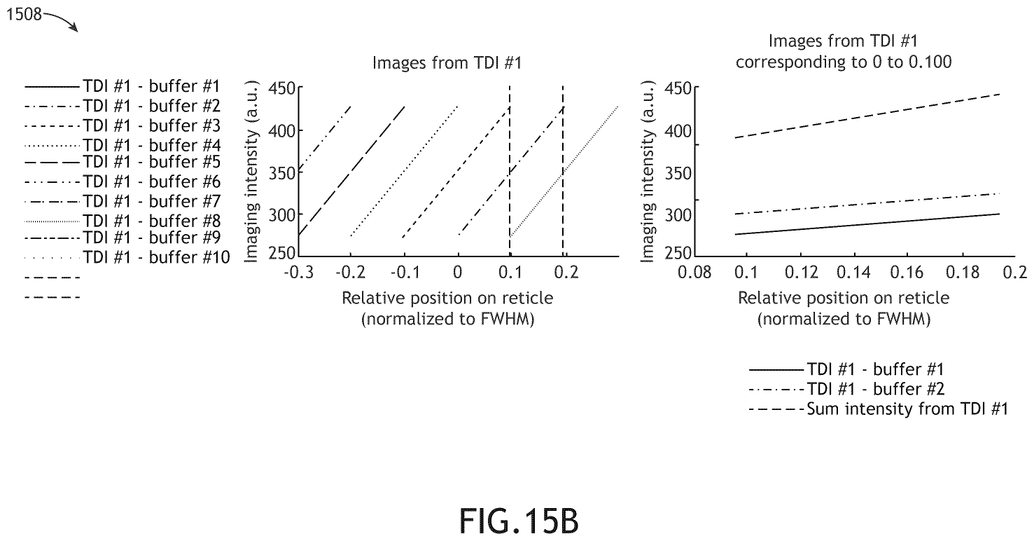

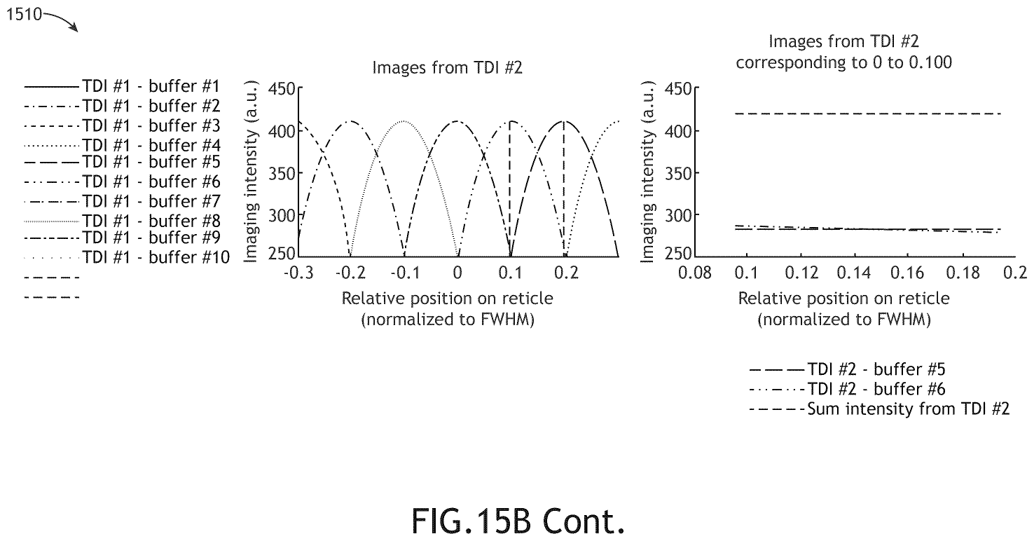

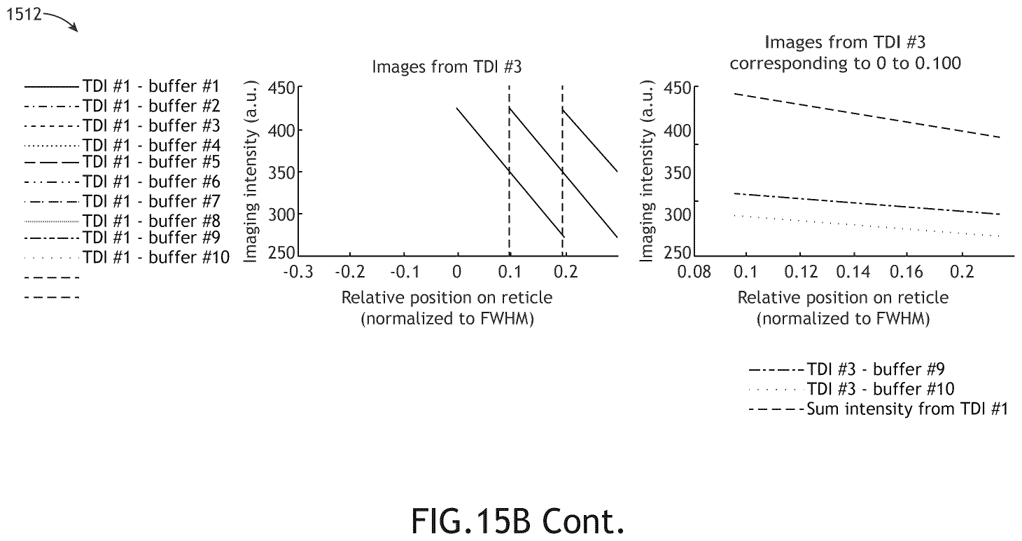

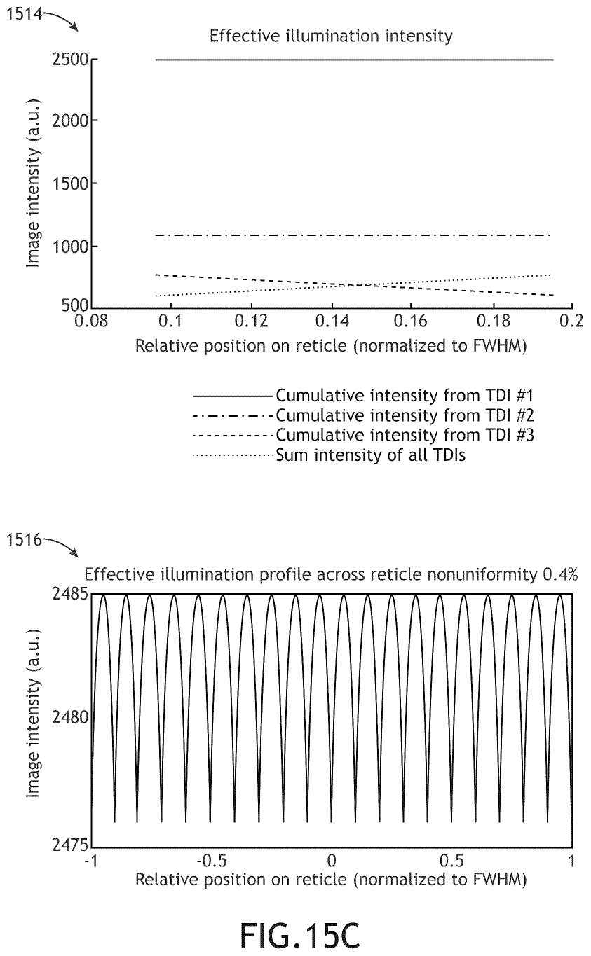

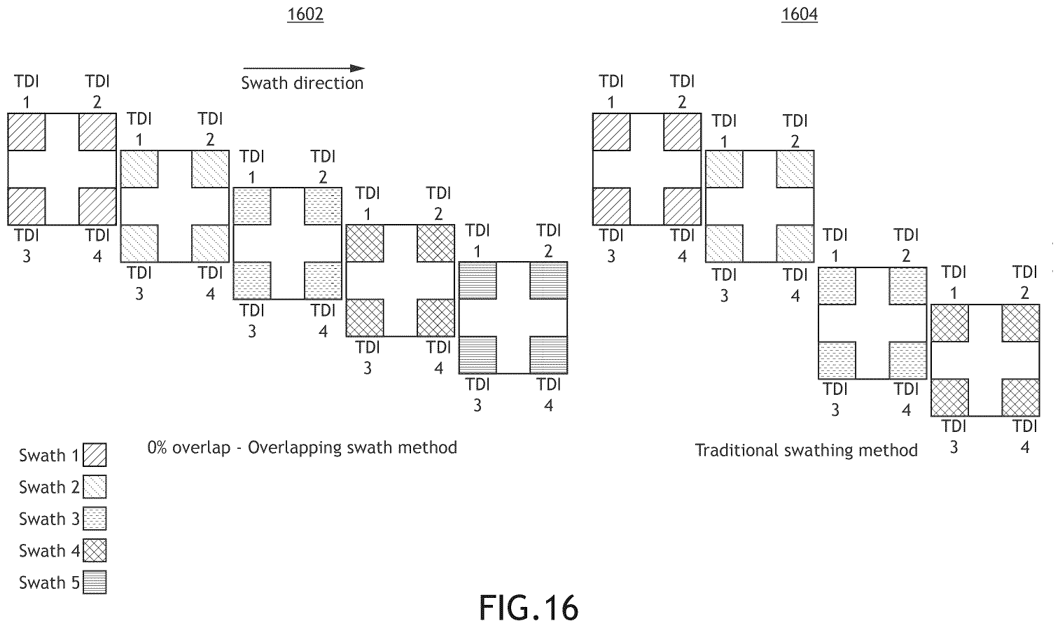

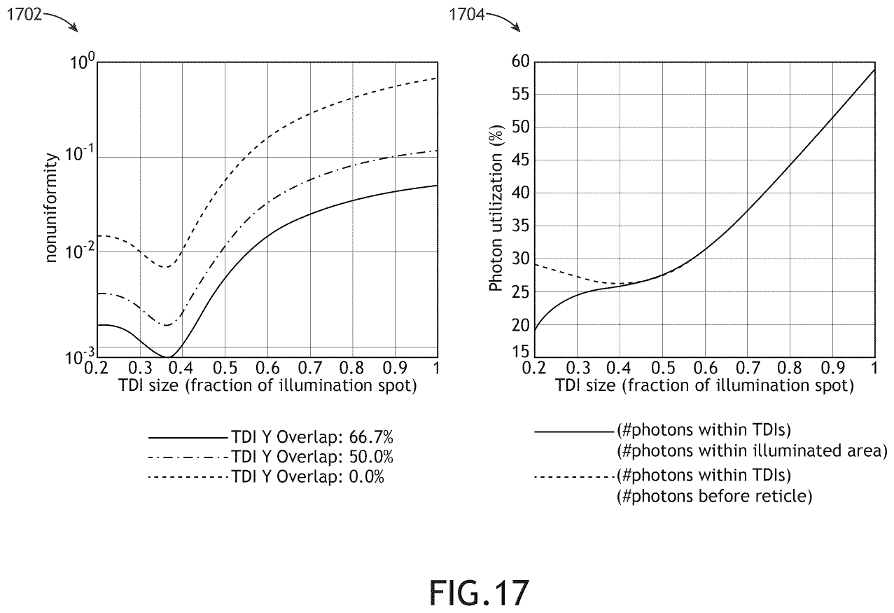

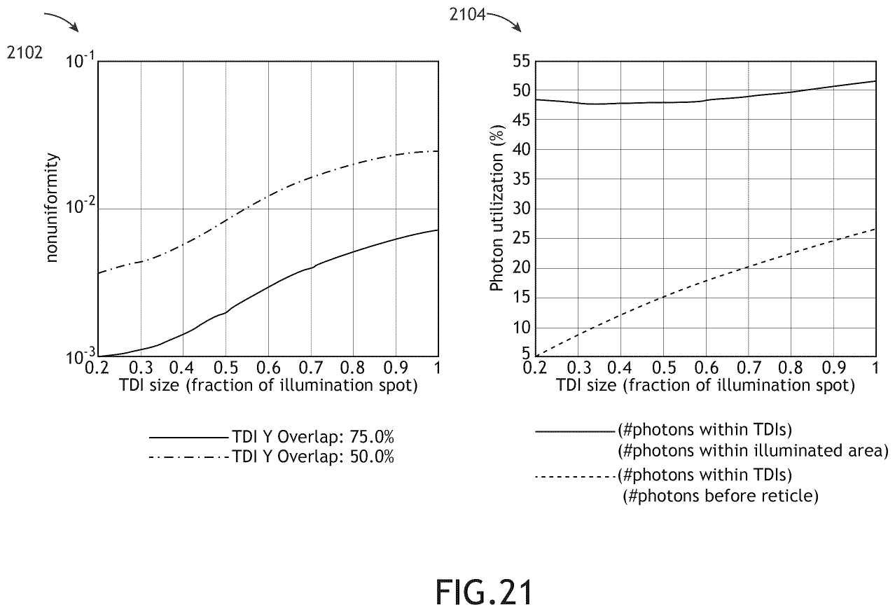

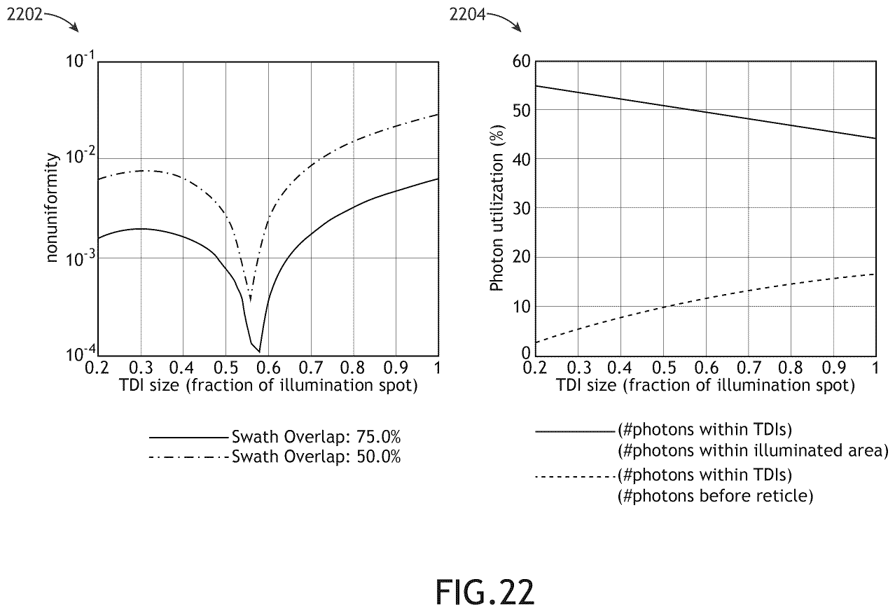

FIGS. 3-6 focus on single TDI sensor configurations with Gaussian illumination beams, demonstrating the relationships between TDI sensor size, illumination uniformity, and photon utilization. FIGS. 7-10 extend this analysis to include inspection time considerations for Gaussian illumination profiles. FIGS. 11-14 the focus to Lorentzian illumination beams, exploring similar parameters and performance metrics for single TDI sensor setups. FIGS. 15-16 introduce multi-TDI sensor configurations, illustrating different swathing methods and uniformity enhancement techniques. FIGS. 17-20 delve into various multi-TDI sensor arrangements with Gaussian illumination, examining the effects of sensor spacing and overlap on uniformity and photon utilization. Finally, FIGS. 21-22 present analyses of multi-TDI sensor configurations with Lorentzian illumination beams. It is to be understood that FIGS. 3-22 are provided solely for illustrative purposes and should not be interpreted as limiting the scope of the present disclosure.

FIG. 3 illustrates imaging with different sizes of a TDI sensor 108 relative to a spot size of a Gaussian illumination beam 106, in accordance with one or more embodiments of the present disclosure.

The figure includes a panel 302, a panel 304, a panel 306, and a panel 308 arranged horizontally, each containing three vertically stacked plots. The top row of each panel includes a 2D illumination profile of the illumination beam 106 (e.g., a beam profile) with an overlay of an imaged field of view of the TDI sensor 108, where the TDI sensor 108 has a decreasing size relative to the beam profile across the panels. The middle row of each panel includes a 1D illumination profile of the illumination beam 106 on the sample 102. This profile is the same for all panels and represents the shape of the illumination profile before being masked by an imaged field of view of the TDI sensor 108. The bottom row of each panel includes a 1D illumination profile after masking by the imaged field of view of the TDI sensor 108.

FIG. 3 demonstrates the relationship between the size of the TDI sensor 108 and the illumination profile of the illumination beam 106. In this example, the illumination beam 106 has a Gaussian beam profile. The size of the TDI sensor 108 in FIG. 3 refers to the size of the imaging field of view associated with the TDI sensor 108, which may be determined by the physical size of the TDI sensor 108 and the magnification of the imaging optics in the swath imaging system 100.

As the size of the imaged field of view of the TDI sensor 108 decreases relative to the beam profile of the illumination beam 106, the illumination uniformity within the imaged field of view increases. This increase in uniformity may be observed by comparing the bottom row plots across the panels from left to right. In panel 302, where the TDI sensor 108 size is large relative to the illumination beam 106, the illumination profile within the imaged field of view shows significant variation. In contrast, in panel 308, where the TDI sensor 108 size is small relative to the illumination beam 106, the illumination profile within the imaged field of view appears more uniform.

As an example, the photon utilization cannot reach 50% when using a Gaussian illumination spot, unless TDI size is greater than 87.5% of the full-width half-maximum (FWHM) of the illumination beam 106. However, the nonuniformity will be worse than 50%. An acceptable nonuniformity threshold may depend on a particular application. A nonuniformity of 10% or smaller is tolerable in some inspection tools. A 10% nonuniformity is obtained only if the TDI size is 40% of the illumination FWHM, which results in a photon utilization below 15%.

However, as the size of the imaged field of view of the TDI sensor 108 decreases, the photon utilization also decreases. Photon utilization in this context refers to the proportion of photons from the illumination beam 106 that fall within the imaged field of view of the TDI sensor 108. In panel 302, where the TDI sensor 108 size is large, a larger proportion of the illumination beam 106 falls within the imaged field of view, resulting in higher photon utilization. In panel 308, where the TDI sensor 108 size is small, a smaller proportion of the illumination beam 106 falls within the imaged field of view, resulting in lower photon utilization.

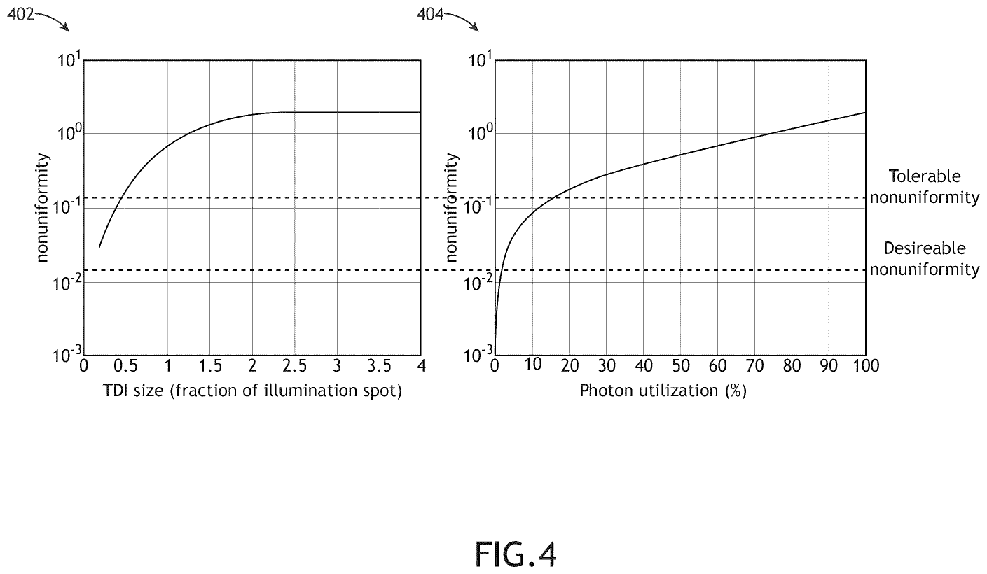

FIG. 4 illustrates two plots illustrating tradeoffs between nonuniformity, TDI sensor size, and photon utilization using a Gaussian illumination beam 106, in accordance with one or more embodiments of the present disclosure. The plot 402 illustrates the relationship between TDI size (fraction of illumination spot covered by imaged field of view of the TDI sensor 108) and nonuniformity. A plot 404 shows the relationship between photon utilization percentage and nonuniformity. Dashed lines extend across plot 402 and plot 404 and indicate indicating tolerable nonuniformity desirable nonuniformity limits for one non-limiting example. Together, the plot 402 and the plot 404 demonstrate how adjusting the TDI size relative to the illumination spot may achieve illumination uniformity at the expense of photon utilization.

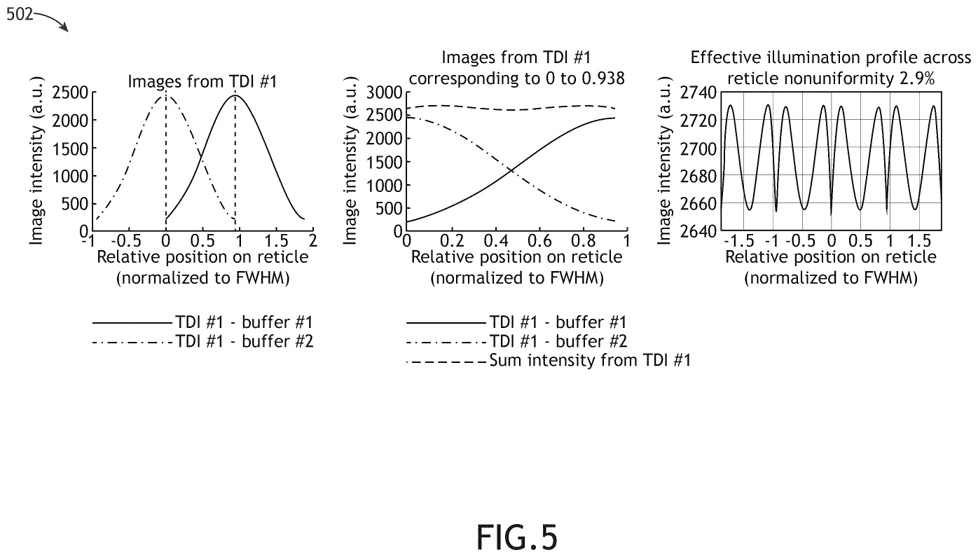

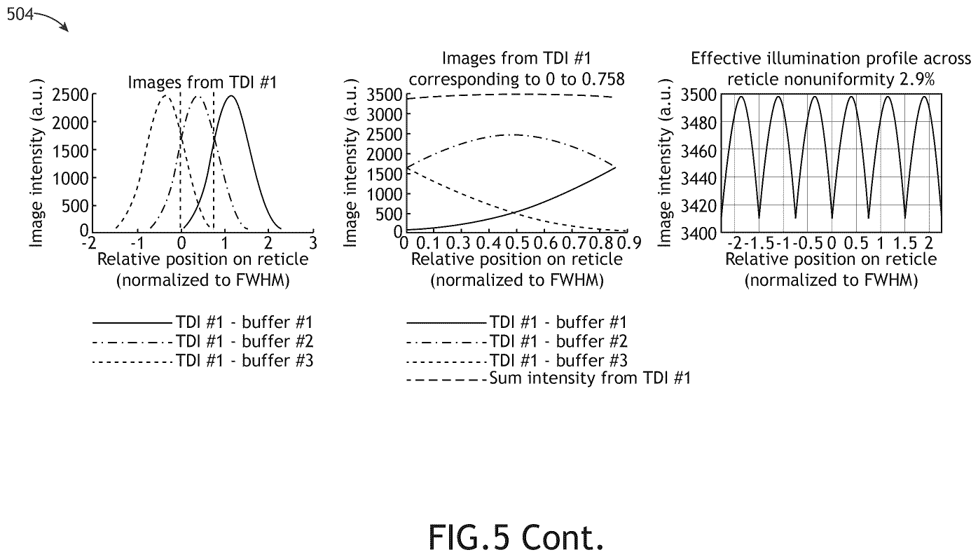

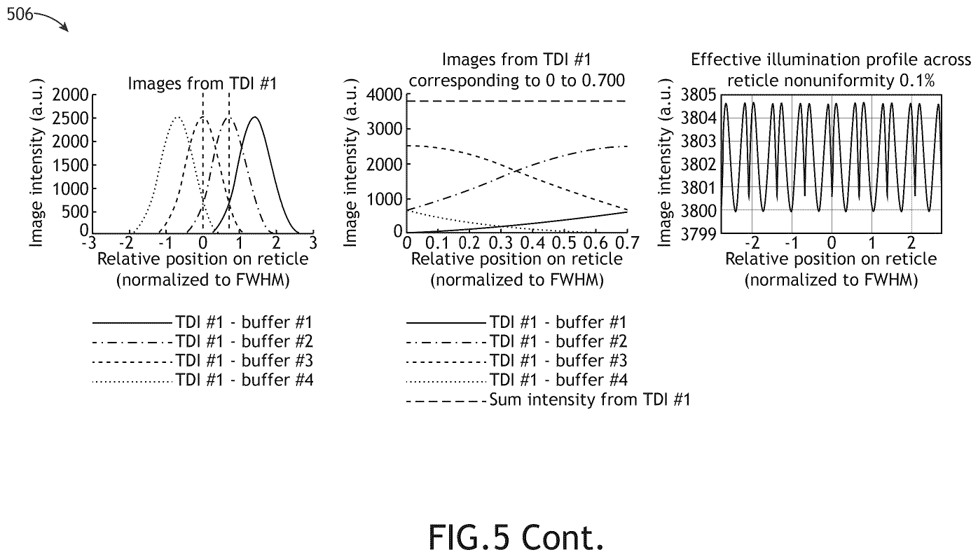

Referring now to FIGS. 5-10, uniformity enhancement by combining overlapping swath images generated with an illumination beam 106 with a Gaussian profile and a single TDI sensor 108 are described in greater detail, in accordance with one or more embodiments of the present disclosure.

In the simulations depicted in FIGS. 5-10, it is assumed that the illumination spot is circularly symmetric and the TDI projection on reticle has a square from factor.

A 2-dimensional Gaussian illumination profile with FWHM diameter of D_{FWHM} (mm) and power W is defined as:

$$I ( x , y ) = \frac{W}{2 π {σ}^{2}} {e}^{- \frac{{x}^{2} + {y}^{2}}{2 {σ}^{2}}} \qquad ( 1 )$$

where

$$σ = \frac{{D}_{1 / {e}^{2}}}{4} = \frac{{D}_{FWHM}}{2 \sqrt{2 ln ( 2 )}} ,$$

and D_{1/e2} (mm) is the 1/e² diameter of the illumination at reticle.

The peak intensity is:

$${I}_{peak} = \frac{W}{2 π {σ}^{2}} = \frac{8 W}{π {D}_{1 / {e}^{2}}^{2}} = \frac{4 ln ( 2 ) W}{π {D}_{FWHM}^{2}} [ W / {mm}^{2} ] \qquad ( 2 )$$

In the normalized domain where D_{FWHM}=1, the peak intensity can be calculated as:

$$\frac{4 ln ( 2 ) W}{π} [ \frac{W}{{D}_{FWHM}^{2}} ] .$$

Assuming the scan direction is along the x-axis and the TDI length in scan direction is arbitrarily large, the scan integrated intensity can be formulated as:

$$I ( y ) [ \frac{W}{mm} ] = {\int }_{- ∞}^{+ ∞} I ( x , y ) dx \cdot T ( y ) = {I}_{peak} σ \sqrt{2 π} {e}^{- \frac{{y}^{2}}{2 {σ}^{2}}} \cdot T ( y ) \qquad ( 3 )$$

where T(y) is a binary function indicating TDI presence (1 when y is within TDI field, 0 otherwise).

The elemental energy detected by one TDI pixel dEₚᵢₓₑₗ(x,y) at position (x,y) over an elemental duration dt is:

$$\begin{matrix}{dE}_{pixel} ( x , y ) = T ( y ) \cdot R \cdot {\int }_{y - \frac{d}{2}}^{y + \frac{d}{2}} {\int }_{y - \frac{d}{2}}^{x + \frac{d}{2}} I ( ζ , η ) τ ( ζ , η ) d ζ d η \times dt \\ \approx T ( y ) \cdot I ( x , y ) {d}^{2} R τ ( x , y ) dt\end{matrix} \qquad ( 4 )$$

where R is the sample 102 reflectivity and τ(x,y) is the combined transmission efficiency of the imaging optics and camera coating.

The energy accumulated by a pixel during one swath can be calculated as:

$${E}_{pixel} ( y ) = T ( y ) \cdot R \cdot τ \cdot {\int }_{- ∞}^{+ ∞} I ( x , y ) {d}^{2} dt = \frac{T ( y ) \cdot R \cdot τ \cdot {d}^{2}}{{v}_{swath}} \frac{2 \sqrt{ln ( 2 )} W}{\sqrt{π} {D}_{FWHM}} {e}^{- \frac{4 ln ( 2 ) {y}^{2}}{{D}_{FWHM}^{2}}} \qquad ( 5 )$$

To limit the photon shot noise, a minimum illumination energy per pixel should be achieved, which is represented as Eₛₕₒₜ. The maximum swathing speed to meet the required energy per pixel Eₛₕₒₜ is:

$${v}_{swath} \leq {min}_{y , where T ( y ) > 0} \frac{T ( y ) \cdot R \cdot τ \cdot {d}^{2}}{{E}_{Shot}} \frac{2 \sqrt{ln ( 2 )} W}{\sqrt{π} {D}_{FWHM}} {e}^{- \frac{4 ln ( 2 ) {y}^{2}}{{D}_{FWHM}^{2}}} \qquad ( 6 )$$

To meet a desirable photon shot noise uniformity across the imaging field, we must impose a uniformity on Eₚᵢₓₑₗ(y), where nonuniformity may be defined as:

$$nonunif = 2 \times \frac{max ( {E}_{pixel} ( y ) ) - min ( {E}_{pixel} ( y ) )}{max ( {E}_{pixel} ( y ) ) + min ( {E}_{pixel} ( y ) )} \qquad ( 7 )$$

To achieve a target nonuniformity, the maximum y may be:

$${y}_{max} = \frac{1}{2 \sqrt{ln ( 2 )}} \sqrt{ln \frac{( 1 + nonunif / 2 )}{( 1 - nonunif / 2 )}} {D}_{FWHM} \qquad ( 8 )$$

In some applications, a recommended TDI size in y direction is twice this value. For example, to reach a nonuniformity of 10% the TDI size should be smaller than 38% of the illumination FWHM in Y direction. In practice to accommodate different mechanical and optical tolerances, the TDI size can be slightly larger than 2yₘₐₓ.

The stage y step may be selected to be smaller than 2yₘₐₓ for two main reasons. First, image processing steps during defect detection may mandate a buffer area (e.g., an erosion zone surrounding the region of interest). Second, stage movement tolerances and drifts may cause in accuracies in y shift. To satisfy both erosion zone and y tolerances needs, there may be certain y overlap (shown by b) between consecutive swaths. Depending on the processing techniques, b may be in a range of 100 to 200 TDI pixels.

The number of swaths to cover an inspection area of L×D may be written as:

$${N}_{swath} = \frac{D}{( 2 {y}_{max} - b )} \qquad ( 9 )$$

where b is the y overlap between consecutive swathes. The time to complete one swath IS t_{swath}=L/v_{swath}. The swath imaging system 100 may then need additional return time (tᵣₑₜ) between swaths to prepare for the next swath. This time encompasses stage acceleration, deceleration, and stabilization. In unidirectional scanning tᵣₑₜ also includes stage retracing back in x direction. Therefore, the total inspection time to cover L×D area is:

$${t}_{scan} = {N}_{swath} ( {t}_{swath} + {t}_{ret} ) = \frac{D}{( 2 {y}_{max} - b )} ( \frac{L}{{v}_{swath}} + {t}_{ret} ) \qquad ( 10 )$$

In the overlapping swath technique, the effective scan integrated intensity will be:

$${I}_{effective} ( y ) = {\sum }_{i = - ∞}^{∞} J ( y - i \times s ) T ( y - i \times s ) \qquad ( 11 )$$

The total energy per pixel can be expressed as:

$${E}_{pixel} ( y ) = \frac{R \cdot τ \cdot {d}^{2}}{{v}_{swath}} \frac{2 \sqrt{ln ( 2 )} W}{\sqrt{π} {D}_{FWHM}} {\sum }_{i = - ∞}^{∞} {e}^{- \frac{4 ln ( 2 ) {( y - i \times S )}^{2}}{{D}_{FWHM}^{2}}} T ( y - i \times S ) \qquad ( 12 )$$

The number of swathes for overlapping swath technique can be approximated by:

$${N}_{swath} = D / S + {N}_{0} \qquad ( 13 )$$

where N₀ is the first and last number of swathes needed to fill the overlapping buffer.

FIG. 5 illustrates achieving illumination uniformity by combining overlapping swath images into a uniformized image using a Gaussian illumination beam 106, in accordance with one or more embodiments of the present disclosure. The figure includes a panel 502, a panel 504, and a panel 506 represented as rows, where each panel includes simulations of different overlap configurations. In each panel, the left column includes a plot showing illumination profiles associated with adjacent swath images (the vertical dashed lines show a step size between center positions of adjacent swaths along the step direction), the middle column includes a plot showing the illumination profiles of the swath images in an overlap region along with an illumination profile in a uniformized image formed by combining (here, summing) the associated swath images, and the right panel includes a plot with a detailed view of the illumination uniformity in the uniformized image in the overlap region.

The panel 502 illustrates an overlap condition where the imaged field of view of the TDI sensor 108 is 1.9 times the FWHM width of the illumination beam 106 and where the overlap between adjacent swaths is 50%, which achieves 2.9% nonuniformity. In this configuration, the photon utilization may be as high as 95%. The panel 504 illustrates an overlap condition where the imaged field of view of the TDI sensor 108 is 2.3 times the FWHM width of the illumination beam 106 and where the overlap between adjacent swaths is 66.7%, which achieves 2.6% nonuniformity. The panel 506 illustrates an overlap condition where the imaged field of view of the TDI sensor 108 is 2.8 times the FWHM width of the illumination beam 106 and where the overlap between adjacent swaths is 75%, which achieves 0.1% nonuniformity.

The overlapping swath imaging technique demonstrated in FIG. 5 may enhance illumination uniformity by combining multiple swath images captured with different portions of the nonuniform illumination beam 106. As the sample 102 is scanned, each location on the sample 102 may be imaged multiple times under different illumination conditions. When these overlapping swath images are combined, the variations in illumination intensity may average out, resulting in a more uniform effective illumination profile in the uniformized image while also maintaining high photon utilization since uniformity of each particular swath image is not required.

The TDI sensor 108 size relative to the illumination beam 106 FWHM and the overlap percentage may be selected to balance uniformity enhancement with other factors such as inspection time and photon utilization. For instance, a 50% overlap between at least some of the plurality of swath images, as shown in the panel 502, may provide a good balance between uniformity improvement and inspection efficiency. In some embodiments, shifts between adjacent swath images may be maintained in a range of 20-50% of the swath width to optimize this balance. A 20% shift may provide maximum uniformity enhancement through high overlap (80% overlap) but may require longer inspection times, while a 50% shift may provide substantial uniformity improvement with more moderate inspection time impact. Shifts in the 30-40% range may offer intermediate performance characteristics, allowing system designers to fine-tune the uniformity-throughput tradeoff based on specific application requirements and constraints.

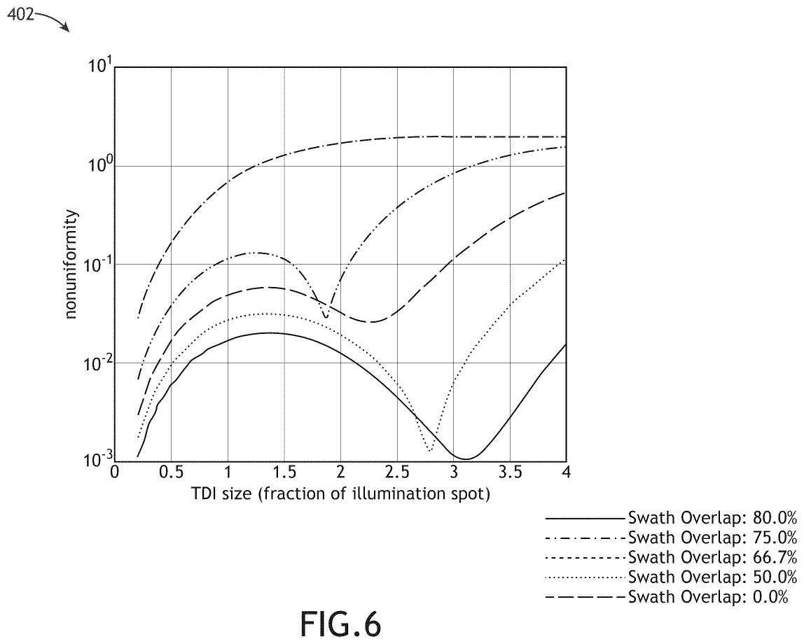

FIG. 6 illustrates a plot 602 showing nonuniformity versus TDI size for different swath overlap percentages using a Gaussian illumination beam, in accordance with one or more embodiments of the present disclosure. The plot 602 includes multiple curves representing swath overlap conditions of 80.0%, 75.0%, 66.7%, 50.0%, and 0.0%.

The plot 602 demonstrates how the size of the TDI sensor 108 (or the size of the imaged field of view of the TDI sensor 108) may be selected for different overlap percentages. In many cases, the plot 602 shows a local minimum, where the image nonuniformity may be minimized (e.g., optimized). In this simulation, all non-zero overlap conditions outperform the 0% overlap condition in terms of achievable nonuniformity. For a swath overlap of 50%, a nonuniformity of 2.9% may be attainable. As the overlap amount increases, uniformity may typically improve and the optimal TDI size may increase.

The information provided in the plot 602 may be used to optimize the TDI sensor 108 size and overlap percentage for specific inspection applications. For example, if a particular application requires a nonuniformity of 2.9% or lower, the plot 602 indicates that this may be achieved with a 50% overlap when the TDI size is approximately 1.9 times the illumination spot size. As another example, a photon utilization of 9% or better may require the TDI size to be larger than 1.6. For a swath overlap of 50%, the TDI size should be between 1.6 and 2.05 to simultaneously satisfy non-limiting 90% utilization and 10% nonuniformity requirements. For the swath overlap of 66.7% and 75% the TDI size should remain smaller than 2.95 and 3.95, respectively, for the nonuniformity to not exceed 10%. The lower limit of 1.6 remains the same regardless of overlap amount. Such a combination of uniformity and photon utilization is not feasible with single swath approach, regardless of TDI size. Further, the smallest nonuniformity (around 0.1%) provided by this simulation is available when TDI size 2.88 and 75% swath overlap are provided. However, it is noted that many applications do not require such strict nonuniformity tolerances such that other combinations of imaging parameters may be utilized in many applications.

Referring now to FIGS. 7-10, the impact of overlapping swaths on overall inspection time (e.g., inspection throughput) is described.

A swath overlap means a greater number of swaths, which my in some cases negatively impact the throughput of the overlapping swath approach. For example, to cover the high fidelity region of a mask (xy=104×132 mm²) with swath width (non-scan direction) of 100 μm, the approximate number of swaths are n(1320), 2n(2640), 3n (3960), and 4n(5280) for 0%, 50%, 66.7%, and 75% swath overlap, respectively. This is an approximation because there will be small overlap for image stitching purposes. Furthermore, there are additional first and last swaths for the overlapping swaths. However, overhead due to these effects is neglected in the simulations provided herein and it is assumed that the number of swaths increases proportional to 1/(1-overlap ratio).

To predict the throughput of the overlapping swath approach, assumptions for two additional parameters are needed: swath overhead and minimum photon count requirements. At the end of each swath, the stage 112 requires time to stop, travel back (in unidirectional swathing scheme), accelerate, and prepare for the next swath. This is referred to as retrace time. Due to this retrace time, the swathing speed must increase more than 2×, 3×, and 4× to maintain throughput same as a non-overlapping swath configuration. In this analysis, retrace times of 2%, 5%, 10% or 15% of swathing time are considered. The actual photons per pixel for the overlapping swath approach is the summation of photons from different swaths which are captured from the same location on the sample 102. The inspection time under different swathing scenarios is analyzed in FIGS. 7-10. The requirement for swathing speed is to meet the required shot noise at the darkest pixel. For non-overlapping technique, this is mainly determined by the darkest illumination field. For overlapping swath, this is evaluated post swath aggregation. To make the comparison easier, a non-overlapping swathing with TDI size of 1 (TDI size same as illumination FWHM) is used as a reference for shot noise and inspection time. Under identical conditions, the overlapping swaths can be done faster and yet achieve the minimum photon requirements after swath aggregation. As shown in FIGS. 7-10, under certain conditions the faster swath speed can compensate for the time increase due to increased number of swaths and retrace time, enabling faster inspection time.

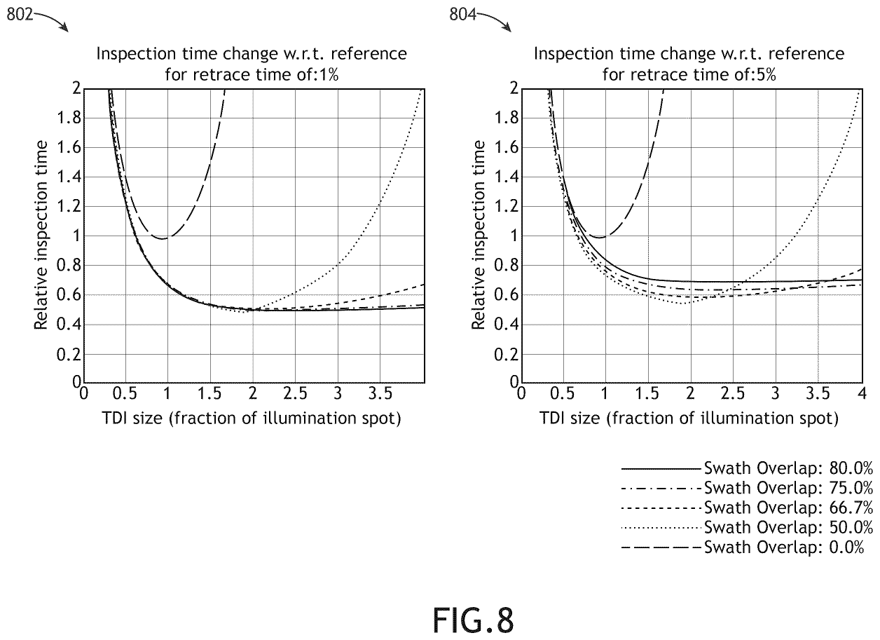

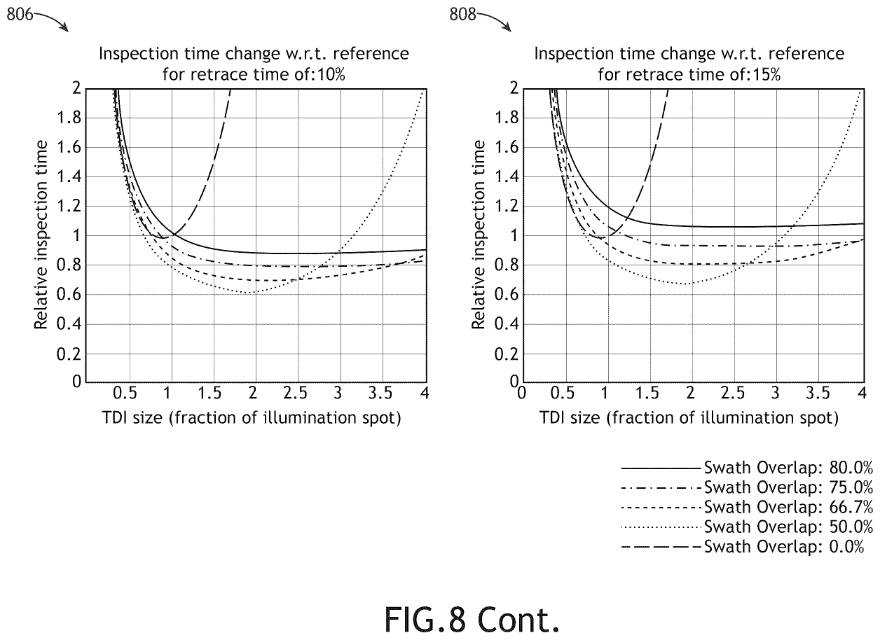

This analysis is performed under two conditions: i) illumination spot size remains constant, but the TDI physical dimensions vary (shown in FIG. 7), and ii) illumination spot size varies, but the TDI physical dimensions remain constant (shown in FIG. 8).

FIG. 7 illustrates relative inspection time as a function of ratio between TDI size and beam size for different overlap percentages, a fixed size Gaussian illumination beam, and varying TDI size, in accordance with one or more embodiments of the present disclosure. The inspection time is set such that minimum of photons for all conditions in this figure are same. The reference inspection time is for a TDI size equal to FWHM and no swathing overlap. Each swath has a fixed overhead time (for stage return and swath preparation). The swath overhead time considered same for reference and the overlapping swath calculations.

FIG. 7 includes four plots, each simulating a different retrace time associated with acceleration, deceleration, and back travel for a unidirectional swathing pattern (all swaths are associated with motion in a common direction). A plot 702 shows the inspection time change with a reference retrace time of 1%, a plot 704 shows the change with a reference retrace time of 5%, a plot 706 shows the change with a reference retrace time of 10%, and a plot 708 shows the change with a reference retrace time of 15%.

In FIG. 7, the illumination spot size remains constant while the TDI physical dimensions vary. Under constant TDI size, when the retrace time is small (1% of reference trace time) all swathing overlaps in this study (50%, 66.7%, 75%, and 80%) outperformed the reference condition. All overlapping swath conditions performed similarly when TDI size is below 1.9, which is close to the optimal TDI size for 50% overlap. At 50% overlap, the swathing time and therefore inspection time increases rapidly as TDI size increases beyond 1.9. Even though a bigger TDI reduces the number of swathes, rapidly increasing nonuniformity forces a longer swath time to meet the photon budget requirements across all pixels.

If the retrace time is relatively large with respect to reference swath time, the impact of greater number of swathes becomes more noticeable. For example, when retrace time is 15% of the reference swath time, at 80% swath overlap the inspection may take as long as 1.5× longer than 50% overlap at same TDI size. This is despite the fact that 80% overlap offers a better uniformity.

FIG. 8 illustrates relative inspection time as a function of ratio between TDI size and beam size for different overlap percentages, a fixed size Gaussian illumination beam, and varying TDI size, in accordance with one or more embodiments of the present disclosure. FIG. 8 is similar to FIG. 7, except that in this figure the TDI size is assumed fixed and the physical size of the illumination spot on the sample 102 is adjusted. Here the number of swathes per sample 102 remains constant. At a fixed mechanical TDI size (illumination spot size changing), a 50% overlap offers excellent throughput.

FIG. 8 includes a plot 802, a plot 804, a plot 806, and a plot 808 associated with retrace times of 1%, 5%, 10%, and 15%, respectively. In the second scenario represented by FIG. 8, the number of swaths does not depend on the TDI/FWHM ratio. Therefore, the swath imaging system 100 does not benefit from reduction in number of swaths at larger TDI/FWHM ratio in this simulation. This is shown in FIG. 8, where at TDI size close to 1, a behavior similar to scenario 1 is observed, but the inspection time is longer than scenario 1 at larger TDI sizes. For large overlap values (75% and 80%), where the nonuniformity is relatively low, the inspection time plateaus, due to the fact that the number of swaths merely depends on the overlap amount and not the TDI/FWHM ratio.

Together, the plots in FIG. 7 and FIG. 8 show that under certain conditions, the overlapping swath imaging may provide both higher illumination uniformity and a faster inspection time than a non-overlap condition. In particular, a faster swath speed may be used, which can compensate for the increased number of swaths and retrace time. However, the plots show that the benefits depend on the retrace time.

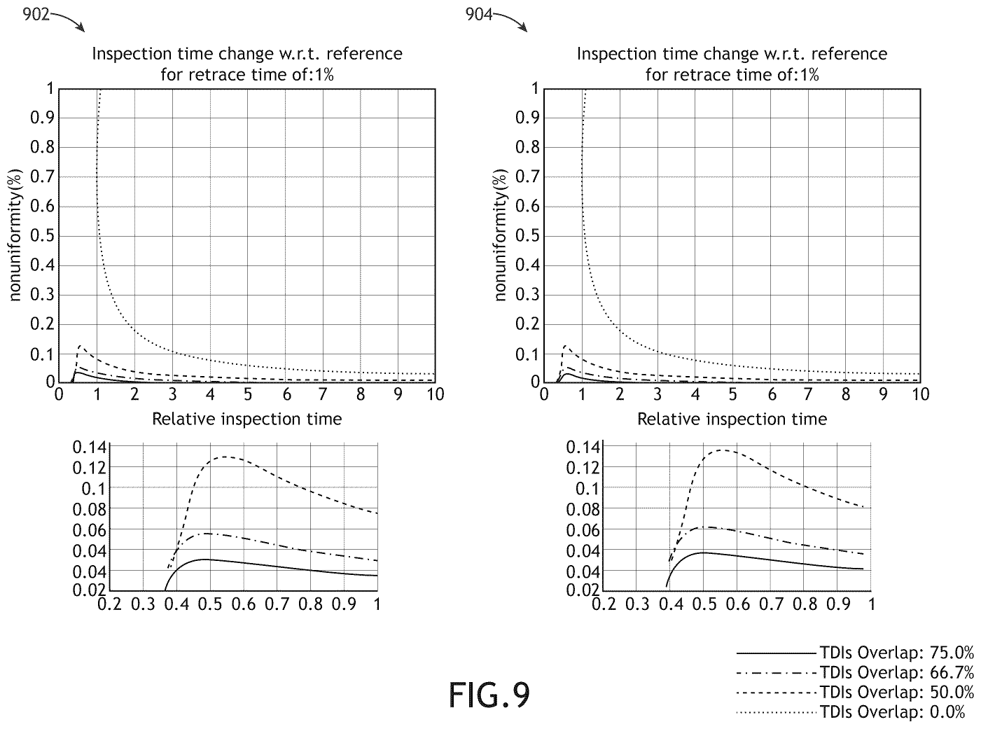

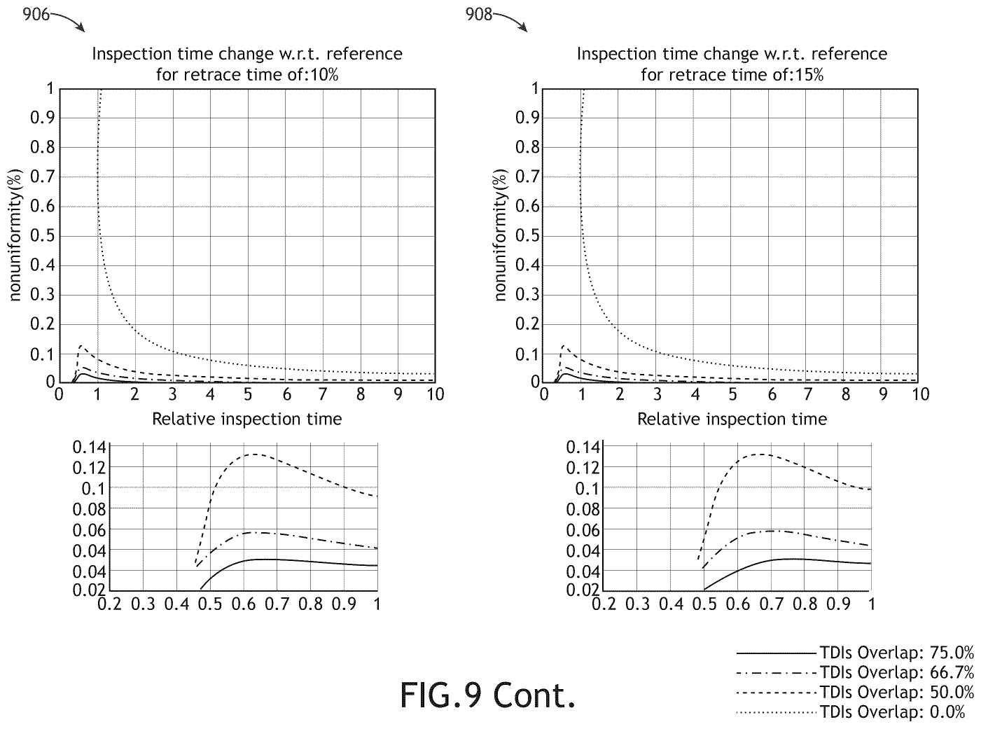

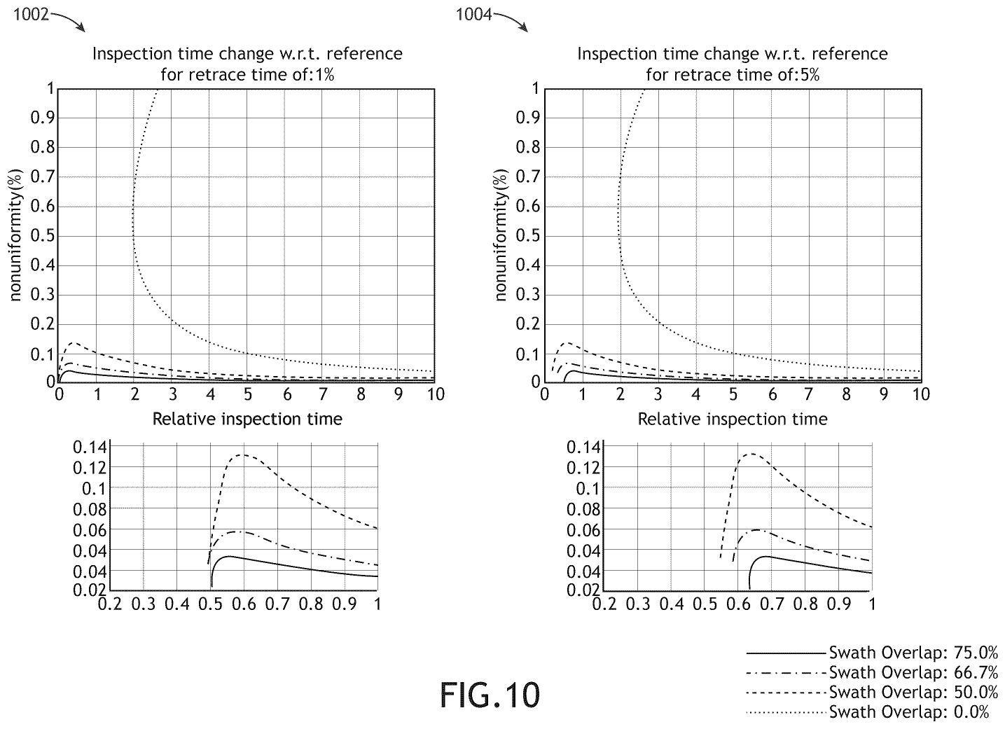

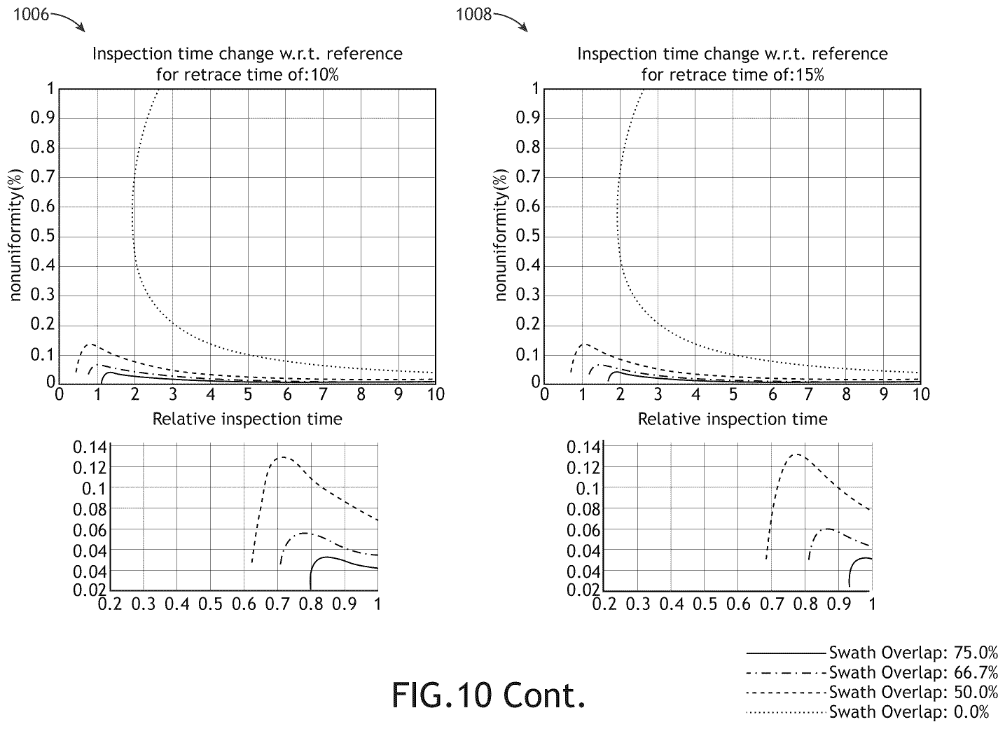

FIGS. 9-10 further illustrate the tradeoffs between image nonuniformity (e.g., in the combined uniformized image) as a function of inspection time.

FIG. 9 illustrates image nonuniformity as a function of inspection time for a Gaussian light source with fixed source size for different overlap percentages and different retrace times, in accordance with one or more embodiments of the present disclosure. FIG. 9 includes a plot 902, a plot 904, a plot 906, and a plot 908. The plot 902 displays inspection time changes with a reference for retrace time of 1%, while the plot 904 shows changes with a reference for retrace time of 5%. The plot 906 illustrates inspection time changes with a reference for retrace time of 10%, and the plot 908 presents changes with a reference for retrace time of 15%.

FIG. 10 illustrates image nonuniformity as a function of inspection time for fixed TDI sensor size and a Gaussian light source with different overlap percentages and different retrace times, in accordance with one or more embodiments of the present disclosure. FIG. 10 includes a plot 1002, a plot 1004, a plot 1006, and a plot 1008. The plot 1002 shows inspection time change with a reference for relative time of 1%, while the plot 1004 displays inspection time change with a reference for relative time of 5%. The plot 1006 illustrates inspection time change with a reference for relative time of 10%, and the plot 1008 presents inspection time change with a reference for relative time of 15%.

It can be seen that even at high retrace time (15% of reference swath time) the inspection time can be lower than half of the traditional inspection while offering a significantly better nonuniformity. If retrace time is short, then a throughput gain of 3× or better can be achieved depending on the overlapping amount. At short retrace time, all overlapping methods have similar inspection times at their optimal TDI size. However, when the retrace time increases, 50% overlap delivers better throughput yet provides and acceptable nonuniformity. A larger overlap between swathes will help to enhance uniformity, but in many applications no such small nonuniformity is required. Therefore, overlapping swath strategy with 50% overlap can be a practical and effective solution for many inspection applications.

The swath imaging system 100 may utilize the relationships demonstrated in FIGS. 5-10 to optimize various imaging parameters based on the specific requirements of a particular application. As illustrated in FIG. 5, different overlap configurations can achieve varying degrees of uniformity enhancement, while FIG. 6 demonstrates how TDI size and overlap percentage interact to affect nonuniformity. FIGS. 7-8 show how these parameters impact inspection time under different conditions, and FIGS. 9-10 illustrate the tradeoffs between nonuniformity and inspection time. It should be emphasized that all of these plots are merely illustrative and represent specific simulation conditions; actual performance may vary based on the specific implementation and operating conditions. The controller 114 may be configured to select illumination conditions, TDI sensor 108 parameters, and stage 112 movement patterns to meet any desired performance metrics for a particular application, such as uniformity targets, photon utilization requirements, or inspection throughput goals. For example, when implementing the method 200, the system may dynamically adjust the overlap percentage between swaths, the TDI sensor size relative to the illumination spot, or the scan speed to achieve an optimal balance between illumination uniformity, photon efficiency, and inspection speed based on application-specific requirements and constraints such as retrace time.

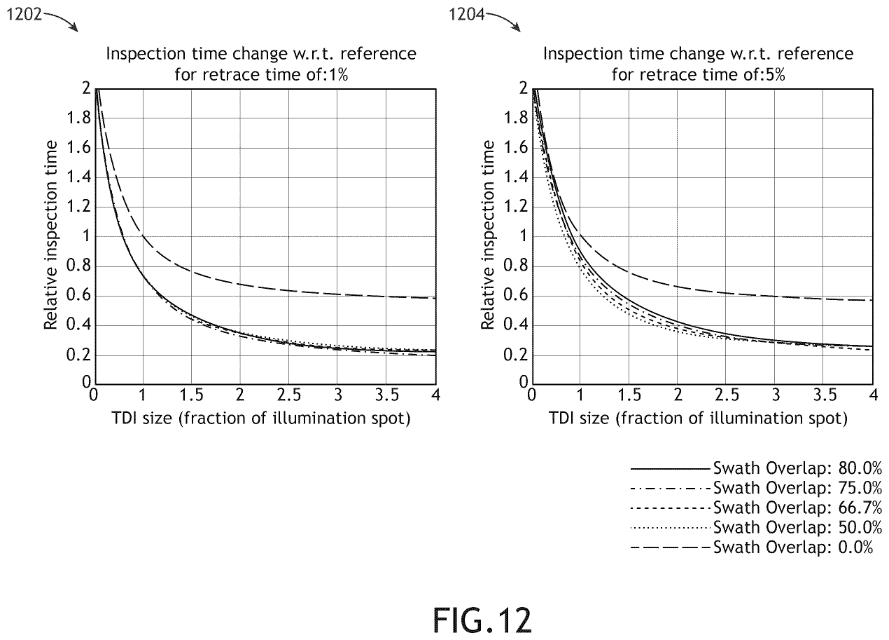

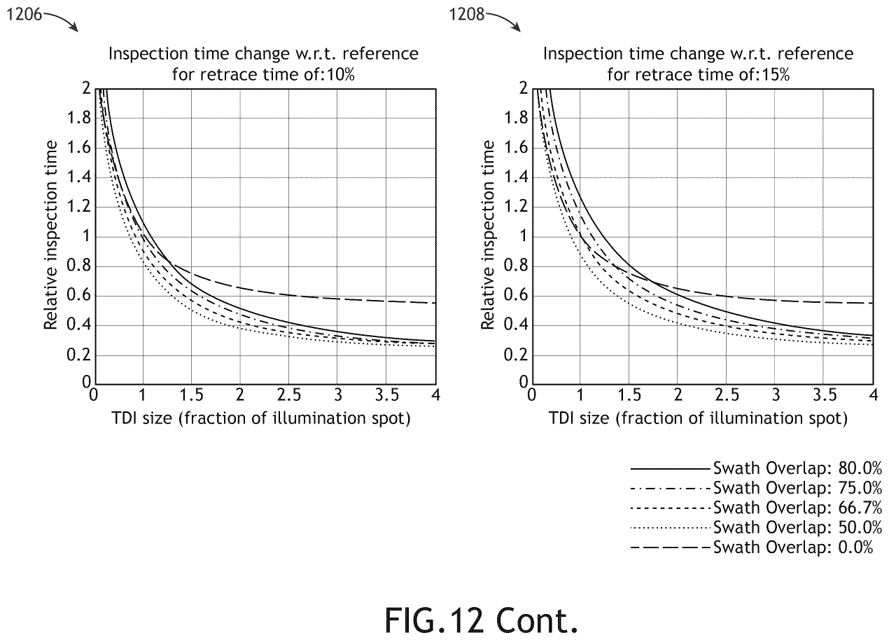

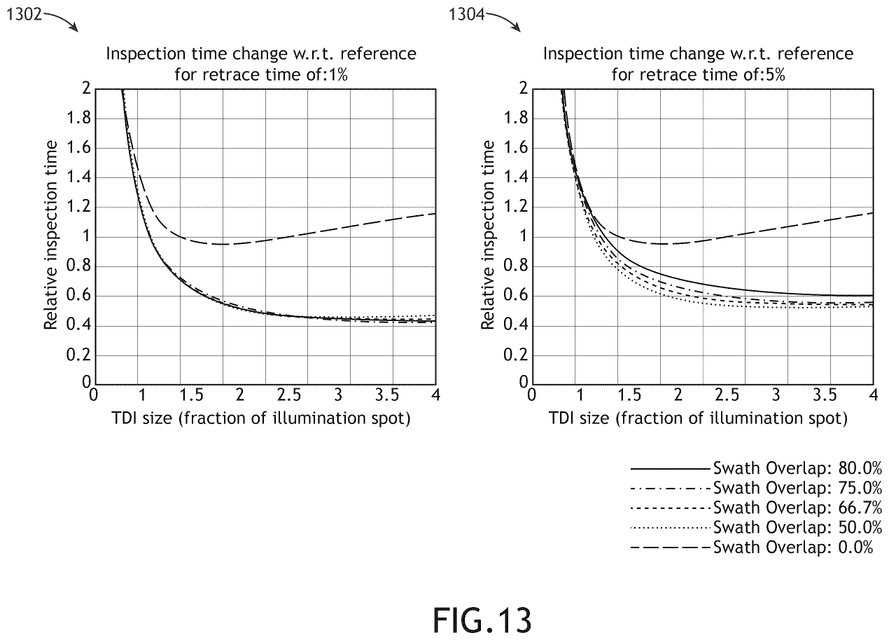

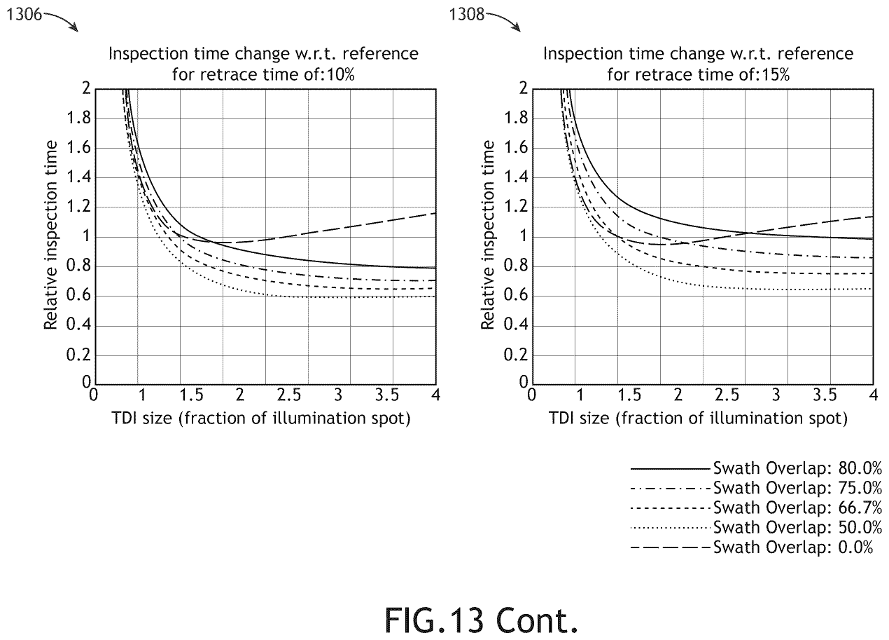

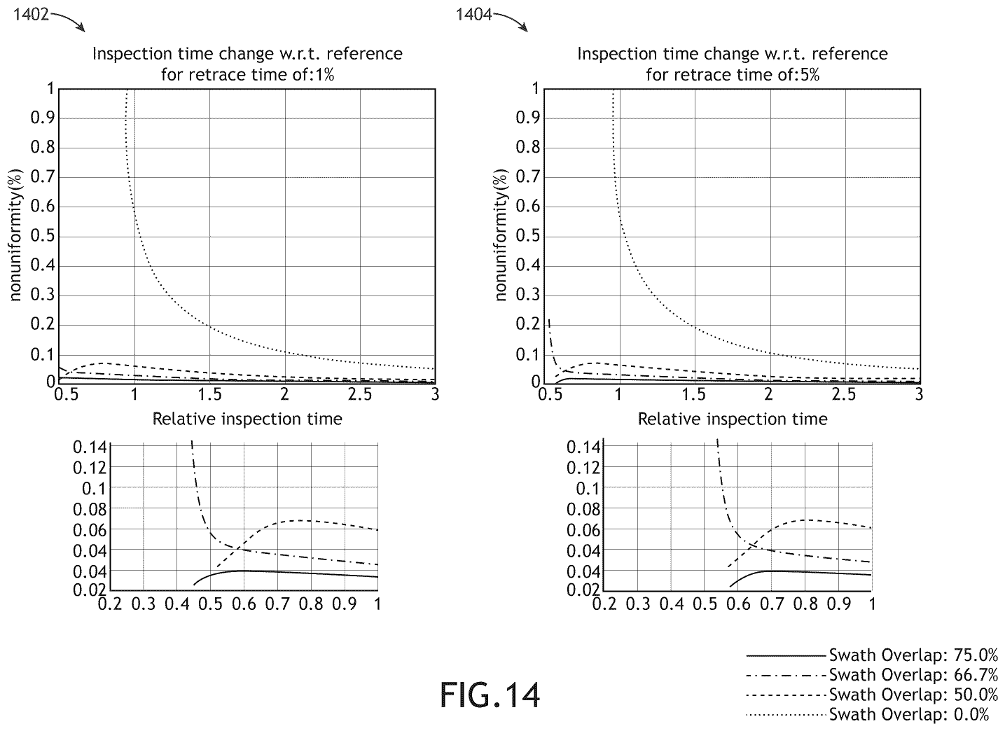

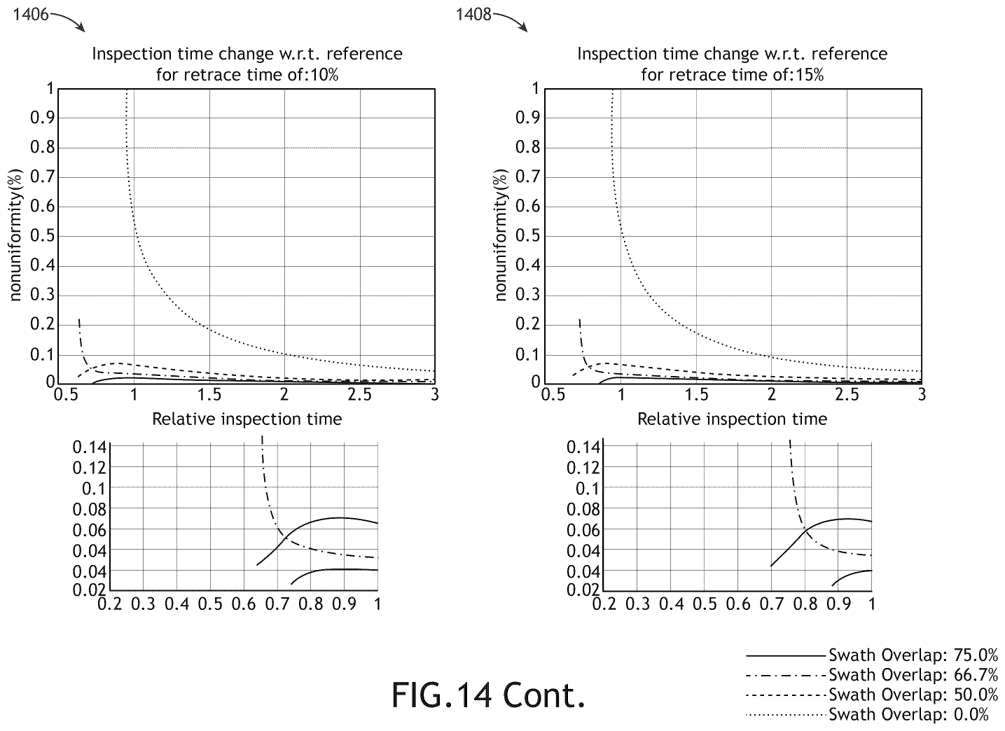

FIGS. 11-14 present simulation results for an swath imaging system 100 utilizing a Lorentzian illumination beam 106 instead of a Gaussian illumination beam. These figures explore the relationships between TDI sensor 108 size, overlap percentage, image nonuniformity, photon utilization, and inspection time for Lorentzian beam profiles. FIG. 11 illustrates the nonuniformity and photon utilization as functions of TDI sensor 108 size for various overlap conditions. FIGS. 12 and 13 demonstrate how inspection time varies with TDI sensor 108 size under different overlap percentages and retrace times, similar to the analysis performed for Gaussian beams in FIGS. 7 and 8. FIG. 14 shows the tradeoffs between image nonuniformity and inspection time for fixed TDI sensor 108 sizes with a Lorentzian light source. These simulations provide insights into how the overlapping swath technique performs with Lorentzian illumination profiles, which may be characteristic of certain types of light sources used in inspection systems.

FIG. 11 illustrates image nonuniformity and photon utilization as a function of TDI sensor size for a Lorentzian illumination beam 106 and a nonoverlapping configuration, in accordance with one or more embodiments of the present disclosure.

The figure includes a plot 1102 showing nonunifority measurements versus TDI size for different swath overlap percentages. A plot 1104 displays photon utilization percentages versus TDI size, a first curve showing photons within TDI versus photons within illuminated area and a second curve showing photons within the TDI versus photons before the reticle (e.g., the sample 102).

With a Lorentzian source and no swath overlap, a nonuniformity of 57% may be achieved when TDI size is equal to the illumination FWHM. This is more uniform than a Gaussian profile under similar conditions. However, the photon utilization for the Lorentzian profile is only 14% compared to 60% for a Gaussian profile. In general, to achieve the same uniformity as a Gaussian profile, a much larger photon loss may be expected with a Lorentzian profile.

FIGS. 12-13 present an analysis of inspection time as a function of TDI size for different overlap percentages using a Lorentzian illumination beam 106. These figures are analogous to FIGS. 7-8, which examined similar relationships for a Gaussian illumination profile.

FIG. 12 illustrates relative inspection time as a function of ratio between TDI size and beam size for different overlap percentages, a fixed size Lorentzian illumination beam, and varying size TDI, in accordance with one or more embodiments of the present disclosure. As with FIGS. 7-8, the inspection time is set such that minimum number of photons for all conditions in this figure are the same. The reference inspection time is for a TDI size equal to FWHM and no swathing overlap. Each swath has a fixed overhead time (for stage return and swath preparation). The swath overhead time considered same for reference and the overlapping swath calculations.

FIG. 12 includes a plot 1202, a plot 1204, a plot 1206, and a plot 1208. The plot 1202 shows the relationship between relative inspection time and TDI size for a 1% reference retrace time, while the plot 1204 displays the same relationship for a 5% reference retrace time. The plot 1206 illustrates the inspection time changes with TDI size for a 10% reference retrace time, and the plot 1208 demonstrates the relationship when using a 15% reference retrace time.

At swath overlap of 50%, a nonuniformity of 2.4% can be achieved if the TDI size is 1.675× of illumination FWHM. Photon utilization is close to 25% at this TDI size. By increasing the overlap amount to 66.7% it is not possible to achieve 2.4% nonuniformity, unless the TDI size reduce to 65% of FWHM, and photon utilization worse than 8%. Unlike Gaussian profile, at this overlap the uniformity monotonically decreases as TDI size increases. A swath overlap of 75% enables a nonuniformity as small as 0.55%, when using an optimal TDI size of 2.675. at this TDI size a photon utilization of 37% can be reached. Generally, if a nonuniformity smaller than 1% is needed w/o significant photon loss, it will be difficult to achieve with Lorentzian source (FIG. 5A). However, in contrast to Gaussian source, if a nonuniformity of 10% is acceptable, Lorentzian source can offer a more diverse selection of TDI/FWHM ratio and swath overlapping amount.

FIG. 13 illustrates relative inspection time as a function of ratio between TDI size and beam size for different overlap percentages, a varying size Lorentzian illumination beam, and fixed size TDI, in accordance with one or more embodiments of the present disclosure. FIG. 13 is similar to FIG. 12, except that in this figure the TDI size is assumed fixed and the physical size of the illumination spot on the sample 102 is adjusted. Here the number of swathes per sample 102 remains constant.

FIG. 13 includes a plot 1302, a plot 1304, a plot 1306, and a plot 1308. The plot 1302 shows the inspection time change with a 1% reference for retrace time, while the plot 1304 displays the inspection time change with a 5% reference for retrace time. The plot 1306 illustrates the inspection time change with a 10% reference for retrace time, and the plot 1308 demonstrates the inspection time change with a 15% reference for retrace time.

With 50% overlap the inspection time is always similar or better than 0% overlap. As overlap size increases, a larger TDI is needed to maintain or improve throughput. In these examples, the physical dimensions of illumination spot size is assumed fixed and the TDI size changes. The number of swathes per reticle reduces as the actual TDI size increases.

FIG. 14 illustrates image nonuniformity as a function of inspection time for a Lorentzian light source with fixed TDI sensor size for different overlap percentages and different retrace times, in accordance with one or more embodiments of the present disclosure. This figure is similar to FIG. 10 except with a Lorentzian beam profile.

The figure includes a plot 1402, a plot 1404, a plot 1406, and a plot 1408. The plot 1402 shows the relationship between relative inspection time and swath overlap percentage for a retrace time of 1%. The plot 1404 displays the same relationship with a retrace time of 5%. The plot 1406 illustrates the inspection time changes with a retrace time of 10%. The plot 1408 demonstrates the relationship between inspection time and swath overlap with a retrace time of 15%.

When studying the nonuniformity as a function of inspection time, the new technique can inspect significantly faster than tradition single swath strategy, while maintaining or even reducing the amount of nonuniformity. In FIG. 14, the overlapping swath technique may achieve higher speeds than traditional non-overlapping swath methods, even at high retrace times (15% for reference swath time). For the overlapping swath method, the minimum source size may be limited to the optimal size. If no optimal size is available, then the minimum size may be 20% of the TDI sensor 108 size.

FIGS. 15A-22 explore multi-TDI sensor configurations for enhancing illumination uniformity in inspection systems. These figures present analyses of various arrangements using multiple TDI sensors 108, which may offer additional flexibility and performance benefits compared to single-sensor configurations in some cases. The multi-TDI approach may allow for more efficient coverage of the sample 102 while still providing overlapping data for uniformity enhancement. FIGS. 15A-15C depict the varying illumination profiles captured by a grid of TDI sensors 108 across a beam profile of a Gaussian illumination beam 106 and how swath images from this configuration may be combined to form a uniformized image, FIG. 16 depicts different swathing techniques, and FIGS. 17-20 examine how parameters such as sensor spacing, overlap percentage, and TDI size affect uniformity and photon utilization for Gaussian illumination profiles. FIGS. 21-22 then extend this analysis to Lorentzian beam profiles.

FIG. 15A illustrates three plots showing illumination profiles captured by an array of TDI sensors 108 distributed across a Gaussian illumination beam 106, in accordance with one or more embodiments of the present disclosure. In particular, this configuration includes a 3×3 grid of TDI sensors 108.

The figure includes a plot 1502 displaying a 2D illumination profile with overlap between the TDI sensors 108 and the Gaussian illumination beam 106. In particular, plot 1502 represents a TDI tile of 3×3 where the TDI size is 0.2× FWHM in both directions. Also TDI gap in both directions is same as the TDI size. A plot 1504 shows a 1D illumination profile before masking, depicting a normalized intensity curve across the position on the sample 102. A plot 1506 presents the intensity profile of swath images formed by three TDI sensors 108 across the profile in the plot 1504. The plot 1506 indicates a nonuniformity measurement of 67% across three images associated with the center column of TDI sensors 108 in plot 1502.

FIG. 15B illustrates achieving image uniformity by combining overlapping swath images from the three TDI sensors 108 distributed along a step direction across a Gaussian illumination beam 106, in accordance with one or more embodiments of the present disclosure. For example, the scan direction may be horizontal in the image and the step direction may be vertical in the image.

The figure includes a panel 1508, a panel 1510, and a panel 1512. Each panel shows two columns, where a first column depicts illumination profiles for overlapping swaths (e.g., in swath images) and a second column depicts combined illumination profiles formed by combining data from overlapping swaths.

The panel 1508 shows illumination profiles for multiple overlapping swaths from a first TDI sensor 108 (e.g., on a top row in the plot 1502). The panel 1510 shows illumination profiles for multiple overlapping swaths from a second TDI sensor 108 (e.g., in a middle row in the plot 1502). The panel 1512 shows illumination profiles for multiple overlapping swaths from a third TDI sensor 108 (e.g., in a bottom row in the plot 1502).

The shapes of the illumination profiles are similar to those shown in the plot 1506, where the panel 1510 corresponding to a center of the illumination beam 106 shows a symmetric illumination profile in a center of the Gaussian distribution, and where the panel 1508 and the panel 1512 show nearly linear profiles associated with edges of the Gaussian distribution.

FIG. 15C illustrates the formation of a uniformized image using the multi-TDI sensor configuration of FIGS. 15A and 15B, in accordance with one or more embodiments of the present disclosure. A plot 1514 shows an illumination profile in a uniformized image associated with a combination of data from panels 1508-1512 of FIG. 15B. A plot 1516 shows a detailed view of the illumination non-uniformity in the uniformized image. In this example, a nonuniformity of 0.4% may be achieved.

It is contemplated herein that configurations using multiple TDI sensors 108 may achieve overlapping swath images using different scan patterns than configurations using a single TDI sensor 108, with each approach having distinct requirements for step sizes between adjacent swaths. In single TDI sensor configurations, achieving overlapping swath images necessitates that step sizes between adjacent swaths along the step direction be smaller than the width of the TDI sensor 108 (or more precisely, smaller than the imaged field of view of the TDI sensor 108 on the sample 102), which ensures that portions of the sample 102 are captured in multiple swath images as the sample 102 is scanned. In contrast, multiple TDI sensor configurations may allow for larger step sizes between adjacent swaths, potentially equal to or greater than the width of an individual TDI sensor 108, because the spatial arrangement of multiple TDI sensors 108 can inherently provide overlap between different sensors even with larger step sizes. In some embodiments, the step sizes along the step direction may be selected as integer fractions of the gap between adjacent TDI sensors 108 along the step direction and/or as integer fraction of a size of at least one of the TDI sensors 108 along the step direction. Such configurations may provide systematic overlapping coverage patterns that avoid unsampled areas enhance uniformity while maintaining efficient scanning throughput. However, it is contemplated herein that various errors or imperfects in by the stage 112, image stitching operations, or the like may result in some unsampled areas. Accordingly, in some embodiments, the step sizes along the step direction may be selected as non-integer fractions of the gap between adjacent TDI sensors 108 along the step direction and/or as integer fraction of a size of at least one of the TDI sensors 108 along the step direction. For example, the step sizes may be selected to be slightly smaller than the gap between adjacent TDI sensors 108 along the step direction and/or as integer fraction of a size of at least one of the TDI sensors 108 along the step direction (e.g., 5% smaller, 10% smaller, or any other suitable value) in order to ensure that there are no unsampled areas.

FIG. 16 illustrates two swathing methods for an inspection system with multiple TDI sensors in a 2×2 grid pattern, in accordance with one or more embodiments of the present disclosure. The panel 1602 depicts an overlap condition in which the sample 102 may be translated by a step size along the step direction equal to a size of each TDI sensor 108. In this configuration, each TDI sensor 108 may have 0% overlap with itself, but may overlap with other TDI sensors 108 to achieve illumination uniformity in a manner similar to the single TDI sensor configuration. In contrast, the panel 1604 depicts a more traditional swathing configuration in which there may be no overlap between any of the TDI sensors 108. In this configuration, the sample 102 may be translated by two alternating step sizes along the step direction to avoid overlap conditions.

The approach depicted in FIG. 16 may be extended to various arrangements of TDI sensors 108 beyond the 2×2 grid pattern shown. For any arbitrary configuration of multiple TDI sensors 108, the swath imaging system 100 may implement either an overlapping or non-overlapping scan pattern.

In an overlapping configuration, the stage 112 may translate the sample 102 using step sizes that correspond to the dimensions of individual TDI sensors 108 or subgroups of sensors. This may allow each physical location on the sample 102 to be imaged by multiple TDI sensors 108, potentially with different illumination conditions.

In some cases, hybrid approaches may be implemented where certain subsets of TDI sensors 108 have overlapping fields of view while others do not. The flexibility in scan patterns may allow the swath imaging system 100 to optimize coverage, uniformity enhancement, and throughput for a wide range of TDI sensor 108 arrangements.

FIGS. 17-20 illustrate image nonuniformity and photon utilization as a function of TDI sensor size for a Gaussian illumination beam 106 for different overlap percentages when using multiple TDI sensors 108 arranged in grid patterns, in accordance with one or more embodiments of the present disclosure.

FIG. 17 illustrates image nonuniformity and photon utilization as a function of TDI sensor size for a Gaussian illumination beam 106 for different overlap percentages when using a 3×3 grid of TDI sensors separated by gaps the same size as the TDI sensors, in accordance with one or more embodiments of the present disclosure. The figure includes a plot 1702 showing nonuniformity measurements versus TDI size (as a fraction of illumination spot) on the x-axis for three different TDI Y overlap conditions. A plot 1704 displays photon utilization percentage on the y-axis versus TDI size on the x-axis, with both dashed and solid line curves representing different measurement conditions.

In the plot 1702, regardless of the overlap amount, the nonuniformity reaches a minimum when TDI size is approximately 0.36× of illumination FWHM with an approximate photon utilization of 25%. This optimal TDI size may provide a balance between uniformity enhancement and photon efficiency for the 3×3 grid configuration with gaps equal to the TDI sensor 108 size. For example, a nonuniformity of 0.4% can be achieved when using 50% overlap between swathes while the photon utilization is 19%. By varying the TDI size the nonuniformity trend at different overlap values can be observed. A photon utilization close to 25% can be achieved with this TDI size. When the TDI size increases beyond 0.7, illumination power in non-central TDIs approaches zero and the 3×3 TDI configuration acts as a single TDI system. For this reason, the TDI size is limited to 1 in the simulation. If the TDI size is limited to smaller than 0.7, with a 50% swath overlap the nonuniformity can be reduced to less than 6% while utilizing around 37% of total photons.

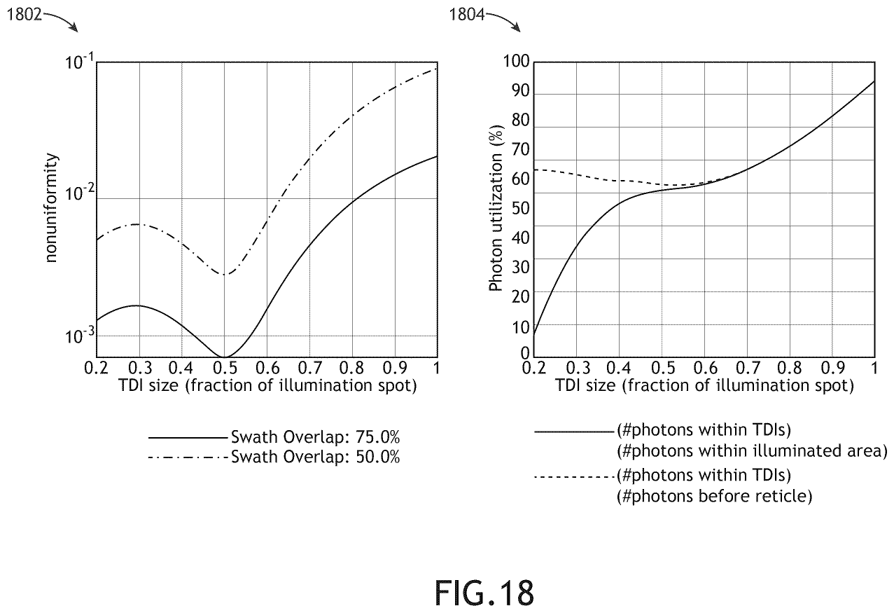

FIG. 18 illustrates image nonuniformity and photon utilization as a function of TDI sensor size for a Gaussian illumination beam 106 for different overlap percentages when using a 3×3 grid of TDI sensors separated by gaps half the size as the TDI sensors, in accordance with one or more embodiments of the present disclosure. The figure includes a plot 1802 showing the relationship between TDI size (fraction of illumination spot) and normalized intensity for different TDI Y overlap percentages of 75.0% and 90.0%. A plot 1804 displays photon utilization percentage versus TDI size (fraction of illumination spot). In the plot 1802, regardless of the overlap amount (50% or 75%), the nonuniformity reaches a minimum when TDI size is approximately half of illumination FWHM. The plot 1804 indicates that photon utilization may reach 45% at this optimal TDI size. For TDI size below 0.62, the nonuniformity may be better than 1%.

Comparing FIG. 17 and FIG. 18, reducing the gap size between TDI sensors 108 in the 3×3 grid configuration may improve both uniformity and photon utilization. The smaller gaps may allow for more efficient coverage of the illumination beam 106 profile while maintaining the benefits of overlapping swaths.

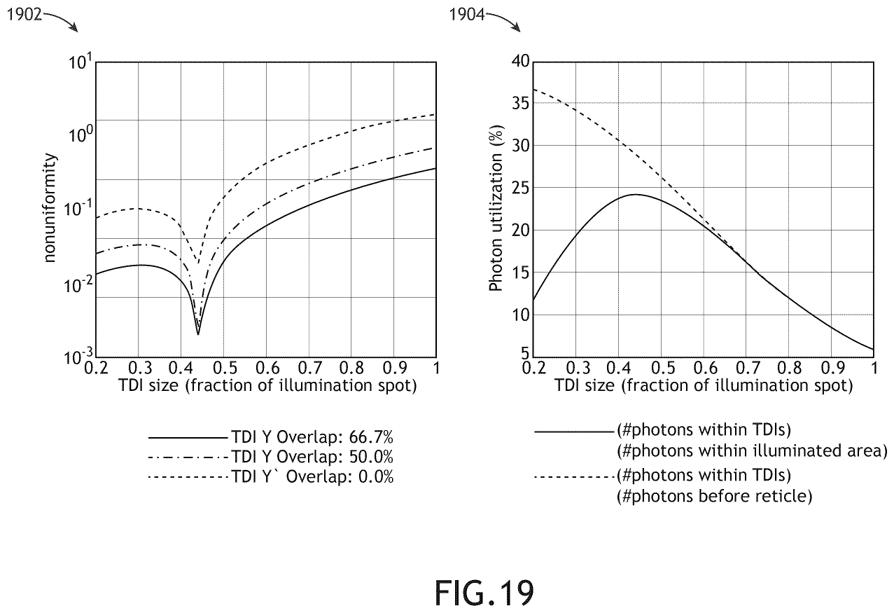

FIG. 19 illustrates image nonuniformity and photon utilization as a function of TDI sensor size for a Gaussian illumination beam 106 for different overlap percentages when using a 2×2 grid of TDI sensors separated by gaps the same size as the TDI sensors, in accordance with one or more embodiments of the present disclosure. The figure includes a plot 1902 showing nonuniformity measurements on a logarithmic y-axis versus TDI size (fraction of illumination spot) on the x-axis for three different TDI Y overlap conditions of 66.7%, 50.0%, and 0.0%. A plot 1904 displays photon utilization percentage on the y-axis versus TDI size (fraction of illumination spot) on the x-axis. In the plot 1902, there may be an optimal TDI size of 0.44 where uniformity may be better than 1% for all overlaps. The plot 1904 indicates that at this optimal TDI size, photon utilization may be at its maximum of 24%.

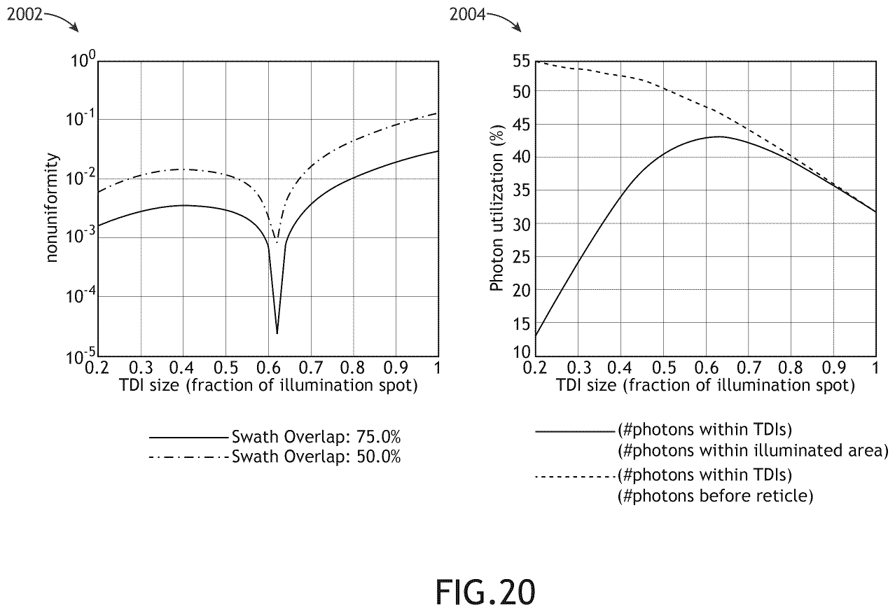

FIG. 20 illustrates image nonuniformity and photon utilization as a function of TDI sensor size for a Gaussian illumination beam 106 for different overlap percentages when using a 2×2 grid of TDI sensors separated by gaps half the size as the TDI sensors, in accordance with one or more embodiments of the present disclosure. The figure includes a plot 2002 showing nonuniformity versus TDI size (fraction of illumination spot) for two overlap conditions-75.0% and 50.0%. A plot 2004 displays photon utilization percentage versus TDI size (fraction of illumination spot). In the plot 2002, for TDI size below 0.67, it may be possible to achieve better than 1% uniformity. The plot 2004 indicates that the optimal TDI size may be 0.62, with maximum photon utilization of 43%.

Comparing FIG. 19 and FIG. 20, reducing the gap size between TDI sensors 108 in the 2×2 grid configuration may improve both uniformity and photon utilization, similar to the trend observed in the 3×3 grid configuration.

FIGS. 21-22 illustrate image nonuniformity and photon utilization as a function of TDI sensor 108 size for a Lorentzian illumination beam 106 for different overlap percentages when using multiple TDI sensors 108 arranged in grid patterns, in accordance with one or more embodiments of the present disclosure. These figures extend the analysis of multi-TDI configurations to Lorentzian beam profiles, which may be characteristic of certain types of illumination sources 104 used in inspection systems 100.

FIG. 21 illustrates image nonuniformity and photon utilization as a function of TDI sensor size for a Lorentzian illumination beam 106 for different overlap percentages when using a 3×3 grid of TDI sensors separated by gaps half the size as the TDI sensors, in accordance with one or more embodiments of the present disclosure. The figure includes a plot 2102 showing nonuniformity versus TDI Y overlap on a logarithmic scale, with two curves representing different overlap conditions of 75.0% and 50.0%. A plot 2104 displays photon utilization percentage versus TDI size (fraction of illumination spot). In the plot 2102, nonuniformity remains below 3%, irrespective of the swath overlap amount. A nonuniformity better than 1% at 50% overlap may be accessible if TDI size is smaller than 0.54, where photon utilization may be worse than 16% as indicated in the plot 2104.

FIG. 22 illustrates image nonuniformity and photon utilization as a function of TDI sensor size for a Lorentzian illumination beam 106 for different overlap percentages when using a 2×2 grid of TDI sensors separated by gaps half the size as the TDI sensors, in accordance with one or more embodiments of the present disclosure. The figure includes a plot 2202 showing TDI Y overlap measurements on a logarithmic y-axis versus TDI size (fraction of illumination spot) on the x-axis, with two curves representing overlap conditions of 75.0% and 50.0%. A plot 2204 displays photon utilization percentage on the y-axis versus TDI size (fraction of illumination spot) on the x-axis. In the plot 2202, 1% nonuniformity may be feasible if TDI size is less than 0.72. The plot 2204 indicates that in this configuration, the photon utilization may be less than 13.5% when achieving this level of uniformity.

Comparing the results from FIG. 21 and FIG. 22, the 3×3 grid configuration may offer slightly better uniformity and photon utilization characteristics compared to the 2×2 grid for Lorentzian illumination beams 106. However, the specific choice between these configurations may depend on factors such as the desired field of view, inspection speed requirements, and the particular characteristics of the sample 102 being inspected.

The multi-TDI configurations analyzed in FIGS. 15A-22 may provide flexibility in managing the tradeoffs between illumination uniformity and photon efficiency when using Gaussian or Lorentzian illumination beams 106. By carefully selecting the TDI sensor 108 size relative to the illumination spot size and adjusting the overlap percentage, the swath imaging system 100 may achieve a balance between uniformity enhancement and photon utilization that may be tailored to specific inspection applications. However, it is to be understood that the present disclosure is not limited to Gaussian or Lorentzian profiles of an illumination beam 106. Rather, the systems and methods disclosed herein may be extended to any non-uniform illumination profile of an illumination beam 106 directed to a sample 102. The swath imaging system 100 or method 200 may select overlapping imaging conditions for an arbitrary beam profile through various approaches. In some cases, the system may perform simulations similar to those illustrated in FIGS. 3-22, but tailored to the specific characteristics of the arbitrary beam profile. These simulations may explore relationships between TDI sensor size, overlap percentage, illumination uniformity, and photon utilization for the given profile. Additionally, the system may conduct experimental measurements using the actual illumination source and TDI sensor configuration to empirically determine optimal imaging conditions. This approach may involve systematically varying parameters such as TDI sensor size, overlap percentage, and scan speed while measuring the resulting uniformity and efficiency metrics. In some implementations, the system may employ machine learning algorithms trained on simulated and experimental data to predict optimal imaging conditions for new beam profiles. The system may also utilize analytical models that describe the behavior of arbitrary beam profiles to derive theoretical optimal conditions, which can then be refined through iterative testing and adjustment.

Referring now to FIG. 1B, additional aspects of the swath imaging system 100 are described in greater detail.

In one embodiment, the swath imaging system 100 includes an illumination source 104 to generate an illumination beam 106. The illumination beam 106 may include one or more selected wavelengths of light including, but not limited to, ultraviolet (UV), extreme ultraviolet (EUV), deep ultraviolet (DUV), or vacuum ultraviolet (VUV) radiation. For example, at least a portion of a spectrum of the illumination beam 106 may include wavelengths below approximately 120 nanometers. By way of another example, at least a portion of a spectrum of the illumination beam 106 may include wavelengths associated with a lithography device suitable for semiconductor fabrication such as, but not limited to, 13.5 nm, 7 nm, or the like.

The illumination source 104 may be any type of illumination source known in the art suitable for generating an optical illumination beam 106. In one embodiment, the illumination source 104 includes a broadband plasma (BBP) illumination source. In this regard, the illumination beam 106 may include radiation emitted by a plasma. For example, a BBP illumination source 104 may include, but is not required to include, one or more pump sources (e.g., one or more lasers) configured to focus into the volume of a gas, causing energy to be absorbed by the gas in order to generate or sustain a plasma suitable for emitting radiation. Further, at least a portion of the plasma radiation may be utilized as the illumination beam 106.

In another embodiment, the illumination source 104 may include one or more lasers capable of emitting radiation at one or more selected wavelengths.

The illumination source 104 may further produce an illumination beam 106 having any temporal profile. For example, the illumination source 104 may produce a continuous illumination beam 106, a pulsed illumination beam 106, or a modulated illumination beam 106.

In another embodiment, the illumination source 104 directs the illumination beam 106 to a sample 102 via an illumination pathway 120. The illumination pathway 120 may include one or more illumination optics 122 suitable for directing, focusing, and/or shaping the illumination beam 106 on the sample 102. For example, the illumination optics 122 may include one or more lenses, one or more focusing elements, or the like. Further, the illumination optics 122 may include any combination of reflective, transmissive, or absorbing optical elements known in the art suitable for directing and/or focusing the illumination beam 106. For instance, the illumination optics 122 may include reflective optics suitable for directing and/or focusing low-wavelength light (e.g., EUV light, and the like) such as, but not limited to, flat mirrors or curved mirrors (e.g., elliptical mirrors, parabolic mirrors, or the like).

The illumination optics 122 may further include one or more additional illumination pathway components suitable for shaping the illumination beam 106 and/or controlling a range of incidence angles of the illumination beam 106 on the sample 102 (e.g., an illumination pupil distribution). For example, the illumination pathway components may include, but are not limited to, one or more apertures, one or more apodizers, one or more homogenizers, one or more diffusers, one or more polarizers, or one or more filters.

In another embodiment, the sample 102 is disposed on a stage 112. The stage 112 may include any device suitable for positioning and/or scanning the sample 102 within the swath imaging system 100. For example, the stage 112 may include any combination of linear translation stages, rotational stages, tip/tilt stages, or the like.

In another embodiment, the swath imaging system 100 includes a TDI sensor 108 configured to capture light emanating from the sample 102 (e.g., sample light 110) through a collection pathway 124. The collection pathway 124 may include, but is not limited to, one or more collection optics 126 for collecting radiation from the sample 102. For example, a TDI sensor 108 may receive sample light 110 reflected or scattered (e.g., via specular reflection, diffuse reflection, and the like) from the sample 102 via the collection optics 126. By way of another example, a TDI sensor 108 may receive sample light 110 generated by the sample 102 (e.g., luminescence associated with absorption of the illumination beam 106, or the like) in response to the illumination beam 106. The collection optics 126 may include any combination of reflective, transmissive, or absorbing optical elements known in the art suitable for directing and/or focusing the sample light 110. For instance, the illumination optics 122 may include reflective optics suitable for directing and/or focusing low-wavelength light (e.g., EUV light, and the like) such as, but not limited to, flat mirrors or curved mirrors (e.g., elliptical mirrors, parabolic mirrors, or the like).

The collection pathway 124 may further include any number of additional collection pathway components to direct and/or shape the sample light 110 from the sample 102 including, but not limited to, one or more apertures, one or more apodizers, one or more polarizers, or one or more filters. In one embodiment, the collection pathway components provide a range of angles within which light is collected from the sample 102 (e.g., an imaging pupil distribution).

Any of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific examples set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A swath imaging system comprising:
an illumination source configured to illuminate a sample with an illumination beam when implementing an inspection recipe;
a stage configured to scan the sample with a scan pattern including a plurality of swaths extending along a scan direction when implementing the inspection recipe, wherein the plurality of swaths are distributed along a step direction orthogonal to the scan direction;
one or more TDI sensors (time-delay-integration sensors) configured to capture a plurality of swath images of the sample associated with the plurality of swaths when implementing the inspection recipe, wherein at least some of the plurality of swath images overlap along the step direction; and
a controller including one or more processors configured to execute program instructions causing the one or more processors to implement the inspection recipe by:
receiving the plurality of swath images;
combining the plurality of swath images into a uniformized image, wherein overlapping portions of the plurality of swath images are combined within the uniformized image; and
generating one or more measurements of the sample based on the uniformized image.

2. The swath imaging system of claim 1, wherein the one or more measurements comprise at least one of inspection measurements or metrology measurements.

3. The swath imaging system of claim 1, wherein combining the plurality of swath images into the uniformized image compensates for imaging nonuniformities caused by at least one of a beam profile of the illumination beam on the sample, nonuniformities caused by one or more optics imaging the sample onto the one or more TDI sensors, or nonuniformities in light responsivity across the one or more TDI sensors.

4. The swath imaging system of claim 3, wherein combining the plurality of swath images into the uniformized image provides that an image nonuniformity metric for the uniformized image is satisfied.

5. The swath imaging system of claim 4, wherein the image nonuniformity metric comprises a measure of variation in at least one of image gray scale intensity, energy per pixel, or photons per pixel across the uniformized image.

6. The swath imaging system of claim 5, wherein the image nonuniformity metric is based on a ratio of a difference between maximum and minimum values to a sum of the maximum and minimum values.

7. The swath imaging system of claim 4, wherein the image nonuniformity metric has a value of 10% or lower.

8. The swath imaging system of claim 4, wherein the image nonuniformity metric has a value of 1% or lower.

9. The swath imaging system of claim 4, wherein one or more imaging parameters used to generate the plurality of swath images are selected to achieve the image nonuniformity metric.

10. The swath imaging system of claim 9, wherein the one or more imaging parameters comprise:
at least one of overlap between the plurality of swath images, a shift between the plurality of swath images along the step direction, a size of at least one of the one or more TDI sensors along the step direction, or a size of the illumination beam on the sample along the step direction.

11. The swath imaging system of claim 9, wherein the one or more TDI sensors comprise two or more TDI sensors, wherein the one or more imaging parameters comprise:
at least one of overlap between the plurality of swath images, a shift between the plurality of swath images along the step direction, a size of at least one of the one or more TDI sensors along the step direction, or a size of the illumination beam on the sample along the step direction, or a separation between at least some of the two or more TDI sensors along the step direction.

12. The swath imaging system of claim 1, wherein combining the plurality of swath images into the uniformized image comprises at least one of summing or averaging the overlapping portions of the plurality of swath images.

13. The swath imaging system of claim 1, wherein a shift between at least some of the plurality of swath images the step direction is in a range of 20-50% of a swath width in the step direction.

14. The swath imaging system of claim 1, wherein a shift between at least some of the plurality of swath images in the step direction is an integer fraction of a size of at least one of the one or more TDI sensors in the step direction.

15. The swath imaging system of claim 1, wherein a shift between at least some of the plurality of swath images in the step direction is smaller than an integer fraction of a size of at least one of the one or more TDI sensors in the step direction.

16. The swath imaging system of claim 1, wherein the one or more TDI sensors comprise a single TDI sensor, wherein at least some adjacent swath images of the plurality of swath images overlap along the step direction.

17. The swath imaging system of claim 1, wherein the one or more TDI sensors comprise two or more TDI sensors, wherein at least some of the two or more TDI sensors are separated by a gap along the step direction, wherein at least some of the plurality of swaths are separated along the step direction by an integer fraction of the gap.

18. The swath imaging system of claim 1, wherein the one or more TDI sensors comprise two or more TDI sensors, wherein at least some of the two or more TDI sensors are separated by a gap along the step direction, wherein at least some of the plurality of swaths are separated along the step direction by a non-integer fraction of the gap.

19. The swath imaging system of claim 1, wherein the one or more TDI sensors comprise two or more TDI sensors, wherein at least some of the plurality of swaths are separated along the step direction by an integer fraction of a size of at least one of the one or more TDI sensors along the step direction.

20. The swath imaging system of claim 1, wherein the one or more TDI sensors comprise two or more TDI sensors, wherein at least some of the plurality of swaths are separated along the step direction by a non-integer fraction of a size of at least one of the one or more TDI sensors along the step direction.

21. The swath imaging system of claim 1, wherein the sample comprises at least one of a wafer or a reticle.

22. The swath imaging system of claim 1, wherein the illumination beam includes wavelengths in an extreme ultraviolet (EUV) spectral region.

23. A swath imaging system comprising:
a controller including one or more processors configured to execute program instructions causing the one or more processors to implement an inspection recipe by:
receiving a plurality of swath images of a sample, wherein the plurality of swath images are captured by one or more TDI sensors (time-delay-integration sensors) during implementation of the inspection recipe, wherein at least some of the plurality of swath images overlap along a step direction;
combining the plurality of swath images into a uniformized image, wherein overlapping portions of the plurality of swath images are combined within the uniformized image; and
generating measurements of the sample based on the uniformized image.

24. The swath imaging system of claim 23, wherein the measurements comprise at least one of inspection measurements or metrology measurements.

25. The swath imaging system of claim 23, wherein combining the plurality of swath images into the uniformized image comprises at least one of summing or averaging the overlapping portions of the plurality of swath images.

26. The swath imaging system of claim 23, wherein combining the plurality of swath images into the uniformized image provides that an image nonuniformity metric for the uniformized image is satisfied.

27. The swath imaging system of claim 26, wherein one or more imaging parameters used to generate the plurality of swath images are selected to achieve the image nonuniformity metric.

28. The swath imaging system of claim 27, wherein the one or more imaging parameters used to generate the plurality of swath images are further selected to achieve a selected inspection time for inspecting a selected portion of the sample.

29. The swath imaging system of claim 28, wherein the selected inspection time is equal to or lower than an inspection time achieved with no overlap between the plurality of swath images.

30. The swath imaging system of claim 27, wherein the one or more imaging parameters used to generate the plurality of swath images are further selected to achieve a photon utilization of an illumination beam while imaging.

31. The swath imaging system of claim 30, wherein the photon utilization is 90% or higher.

32. The swath imaging system of claim 30, wherein the photon utilization is 25% or higher.

33. The swath imaging system of claim 23, wherein the one or more TDI sensors comprise a single TDI sensor, wherein at least some adjacent swath images of the plurality of swath images overlap along the step direction.

34. The swath imaging system of claim 23, wherein the one or more TDI sensors comprise two or more TDI sensors, wherein at least some of the two or more TDI sensors are separated by a gap along the step direction, and at least some of the plurality of swath images are separated along the step direction by an integer fraction of the gap.

35. A method, comprising:
illuminating a sample with an illumination beam having a nonuniform beam profile;
scanning the sample with a scan pattern including a plurality of swaths extending along a scan direction, wherein the plurality of swaths are distributed along a step direction orthogonal to the scan direction;
capturing, using one or more TDI sensors (time-delay-integration sensors), a plurality of swath images of the sample associated with the plurality of swaths, wherein at least some of the plurality of swath images overlap along the step direction;
combining the plurality of swath images into a uniformized image, wherein overlapping portions of the plurality of swath images are combined within the uniformized image; and
generating measurements of the sample based on the uniformized image.
